(19) United States
(12) Patent Application Publication
(10) Pub. No.: US 2026/0331182 A1
(43) Pub. Date: Oct. 22, 2026

(54) MEMORY DEVICE AND METHOD OF DETECTING INFORMATION STATE OF MEMORY CELL OF MEMORY DEVICE

(71) Applicant: Taiwan Semiconductor Manufacturing Company, Ltd., Hsinchu (TW)

(72) Inventors: Ryota WATANABE, Hsinchu (TW); Hidemitsu KOJIMA, Hsinchu (TW); Kazumasa UNO, Hsinchu (TW); Hiromasa OTSUBO, Hsinchu (TW)

(73) Assignee: Taiwan Semiconductor Manufacturing Company, Ltd., Hsinchu (TW)

(21) Appl. No.: 19/183,751

(22) Filed: Apr. 18, 2025

(51) Int. Cl. G11C 16/26; G11C 16/24; G11C 16/30

(52) U.S. Cl. CPC G11C 16/26; G11C 16/24; G11C 16/30

(57) ABSTRACT

An embodiment memory device includes a memory cell array including a plurality of memory cells and a plurality of sets of N bit lines arranged in association with corresponding columns of memory cells of the memory cell array. Each memory cell of the memory cell array includes a transistor, and two drain/source terminals of the transistor are electrically coupled to a same bit line or two bit lines of a corresponding set of N bit lines of the plurality of sets of N bit lines, and an electrical coupling relationship between the two drain/source terminals and the corresponding set of N bit lines indicating one of

$$\{ \frac{1}{2} N ( N - 1 ) + 1 \}$$

candidate information states.

### BACKGROUND

Modern integrated circuit (IC) manufacturing technology enables faster, smaller, and more efficient devices. In many applications, the size of electrical components and transistors have shrunk to include more components in a semiconductor die, or even more layers of components in a semiconductor die. These advances in IC manufacturing technology have supported the development of a wide variety of digital devices, such as a semiconductor device including one or more memory devices for storing information.

In some applications, the one or more memory devices are implemented based on one or more types of memory technology that correspond to one or more of a read-only memory (ROM) device, an erasable programmable read only memory (EEPROM) device, a static random access memory (SRAM) device, a dynamic random access memory (DRAM) device, or the like. In some applications, a ROM device is configured to store fixed information that is not changeable after the manufacturing of the ROM device is completed. In some applications, a ROM device is a non-volatile memory device, as the ROM device retains the stored information even when the power to the ROM device is removed. There are also studies regarding increasing the data density of each memory cell of a ROM device in order to increase the storage capacity and/or reduce the size of the ROM device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic block diagram of a memory device, in accordance with some embodiments.

FIG. 2A is a schematic diagram of a memory cell in association with a set of bit lines, in accordance with some embodiments.

FIG. 2B is a simplified table of candidate information states of the memory cell in FIG. 2A, in accordance with some embodiments.

FIG. 2C includes schematic diagrams of the memory cell in FIG. 2A with various electrical coupling settings, in accordance with some embodiments.

FIG. 2D is a table of candidate information states summarizing various electrical coupling settings in FIG. 2C, in accordance with some embodiments.

FIG. 3A is a schematic block diagram of a memory device based on a first output circuitry configuration, in accordance with some embodiments.

FIG. 3B is a schematic diagram of a portion of the memory device in FIG. 3A, including a column of memory cells in association with a set of bit lines, and including a portion of the output circuitry of the memory device electrically coupled to the set of bit lines, in accordance with some embodiments.

FIG. 3C is a schematic diagram of the portion of the output circuitry of the memory device in FIG. 3B, in accordance with some embodiments.

FIG. 4A is a timing diagram of various control signals for controlling a reading cycle of the sense circuitry in FIG. 3B, in accordance with some embodiments.

FIGS. 4B-4E are timing diagrams of signals at various terminals of the sense circuitry in FIG. 3B based on detecting different information states, in accordance with some embodiments.

FIG. 5A is a schematic diagram of a portion of a memory device, including a column of memory cells in association with a set of bit lines, and including a portion of an output circuitry of the memory device electrically coupled to the set of bit lines, in accordance with some embodiments.

FIG. 5B is a schematic diagram of the portion of the output circuitry of the memory device in FIG. 5A, in accordance with some embodiments.

FIG. 5C is a timing diagram of various control signals for controlling a reading cycle of the sense circuitry in FIG. 5B, in accordance with some embodiments.

FIG. 6A is a schematic diagram of a portion of a memory device, including a column of memory cells in association with a set of bit lines, and including a portion of the output circuitry of the memory device electrically coupled to the set of bit lines, in accordance with some embodiments.

FIG. 6B is a schematic diagram of the portion of the output circuitry of the memory device in FIG. 6A, in accordance with some embodiments.

FIG. 7 is a schematic diagram of a portion of a memory device, including a column of memory cells in association with a set of bit lines, and including a portion of an output circuitry of the memory device electrically coupled to the set of bit lines, in accordance with some embodiments.

FIGS. 8A-8C are schematic diagrams of output circuitry examples that include holders, in accordance with some embodiments.

FIGS. 9A-9B are schematic diagrams of decoder examples, in accordance with some embodiments.

FIG. 10A is a schematic diagram of a sub-array including two memory cells based on n-type transistors and in association with a set of bit lines, in accordance with some embodiments.

FIG. 10B includes schematic diagrams of a memory cell in FIG. 10A with various electrical coupling settings, in accordance with some embodiments.

FIG. 11A is a schematic diagram of a sub-array including two memory cells based on p-type transistors and in association with a set of bit lines, in accordance with some embodiments.

FIG. 11B includes schematic diagrams of a memory cell in FIG. 10A with various electrical coupling settings, in accordance with some embodiments.

FIG. 12A is a schematic block diagram of a memory device 1200 based on a second output circuitry configuration, in accordance with some embodiments.

FIG. 12B is a schematic diagram of a portion of a memory device, including a column of memory cells in association with a set of bit lines, and including a sense circuitry, in accordance with some embodiments.

FIG. 12C is a schematic diagram of a portion of another memory device, including a column of memory cells in association with a set of bit lines, and including a sense circuitry, in accordance with some embodiments.

FIG. 13 is a flowchart of a method of detecting an information state of a memory cell of a memory device, in accordance with some embodiments.

FIG. 14 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

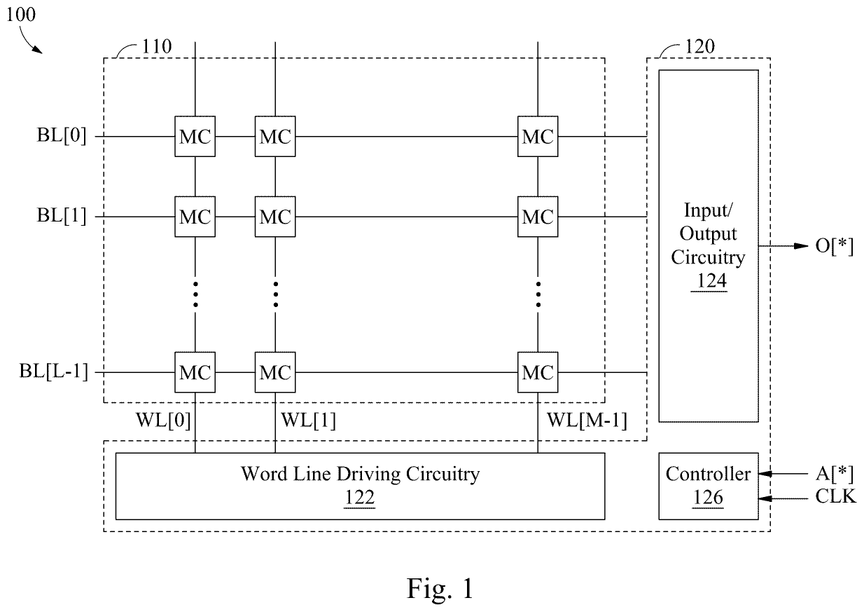

FIG. 1 is a schematic block diagram of a memory device 100, in accordance with some embodiments. In some embodiments, memory device 100 is included in a semiconductor device. In some embodiments, the semiconductor device that includes memory device 100 further includes other components and/or circuitry for other functionalities. In this non-limiting example, memory device 100 corresponds to a read-only memory (ROM) device.

In FIG. 1, memory device 100 includes a memory cell array 110 and control circuitry 120 coupled to memory cell array 110. Memory cell array 110 includes memory cells (labeled as “MC” in FIG. 1) arranged in rows and columns. In some embodiments, control circuitry 120 is configured to control operations of the memory cells of memory cell array 110. In FIG. 1, as a non-limiting example, memory device 100 further includes a plurality of word lines WL[0] to WL[M−1] extending along a row direction and a plurality of sets of bit lines BL[0] to BL[L−1] extending along a column direction. In some embodiments, each set of the plurality of sets of bit lines includes N bit lines. Each of the memory cells MC is coupled to control circuitry 120 by at least one of the word lines and at least one set of the plurality of sets of bit lines. In some embodiments, M, L, and N are positive integers. The word lines are also referred to in this disclosure as WL, and the bit lines are also referred to in this disclosure as BL. Various numbers of word lines and/or bit lines in memory device 100 are within the scope of various embodiments.

In FIG. 1 as a non-limiting example, control circuitry 120 includes a word line driving circuitry 122, an input/output circuitry 124, and a controller 126. In some embodiments, the word line driving circuitry 122 includes word line drivers and/or an address decoder. In some embodiments, input/output circuitry 124 includes sensing circuits, pre-charging circuits, keeper circuits, multiplexers for selecting output signals, and/or latches for holding the output signals.

In some embodiments, controller 126 includes internal timing generators, pre-decoders for interpreting an address, and/or latches for holding input signals. In this example, controller 126 receives an address A[*] of a memory cell to be accessed during a read operation and a system clock signal CLK. In some embodiments, controller 126 generates various control signals and/or internal clock signals based on the system clock signal CLK. In some embodiments, controller 126 and/or the address decoder included in word line driving circuitry 122 interpret at least a portion of the address A[*] and activate a corresponding one of the word line drivers included in word line driving circuitry 122 to active one of the word lines that corresponds to the address. In some embodiments, the selected one of the word line drivers included in word line driving circuitry 122 activates a specific row based on activating the corresponding word line to enable access to the memory cells in the row.

In some embodiments, controller 126 and/or input/output circuitry 124 interpret at least another portion of the address A[*] and activate a portion of the sensing circuits, pre-charging circuits, and/or keeper circuits included in input/output circuitry 124 and coupled to one set of the plurality sets of bit lines based on the decoded portion of the address. In some embodiments, the selected portion of input/output circuitry 124 is configured to read the stored information stored in the memory cell specified by the decoded row and column via the corresponding bit line and output the stored information as the output binary data O[*].

In FIG. 1, memory device 100 includes one memory cell array 110 as a non-limiting example. In some embodiments, a memory device includes one or more memory cell arrays sharing a portion or all of one control circuitry (e.g., sharing controller 126, sharing word line driving circuitry 122 and controller 126, sharing a portion or all of input/output circuitry 124, sharing entire control circuitry 120, or the like).

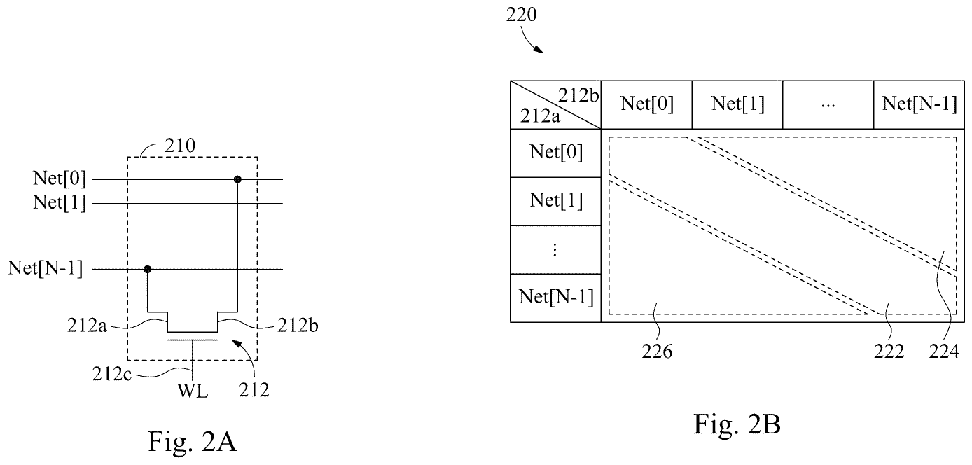

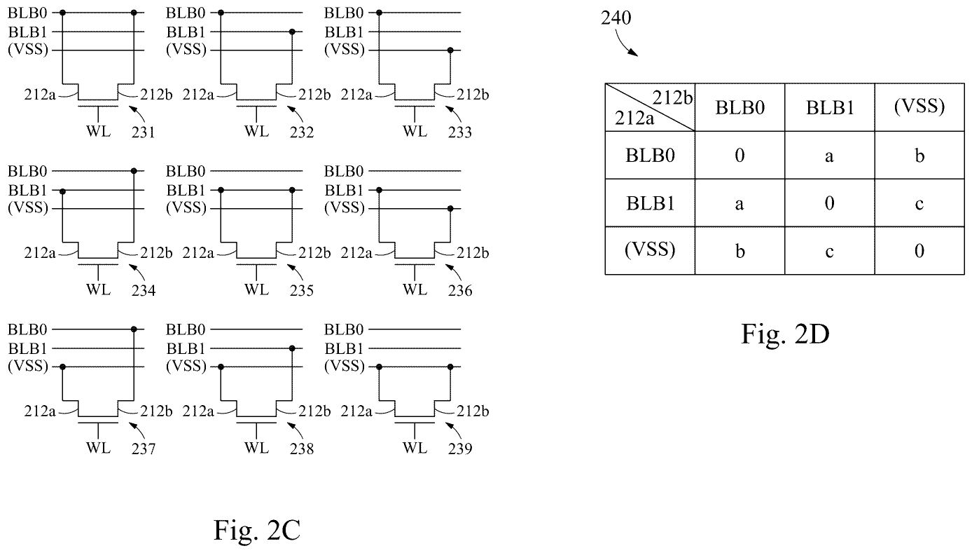

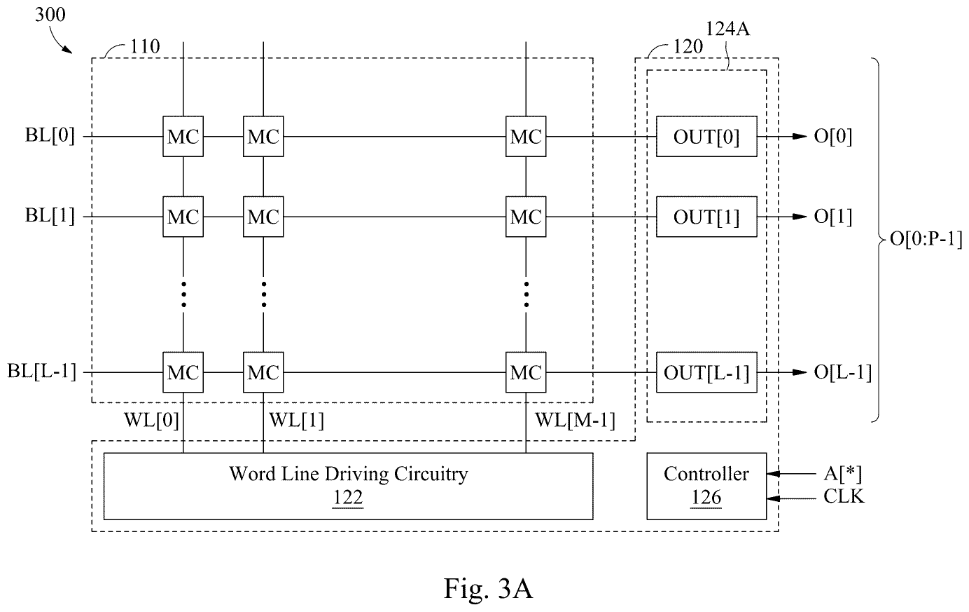

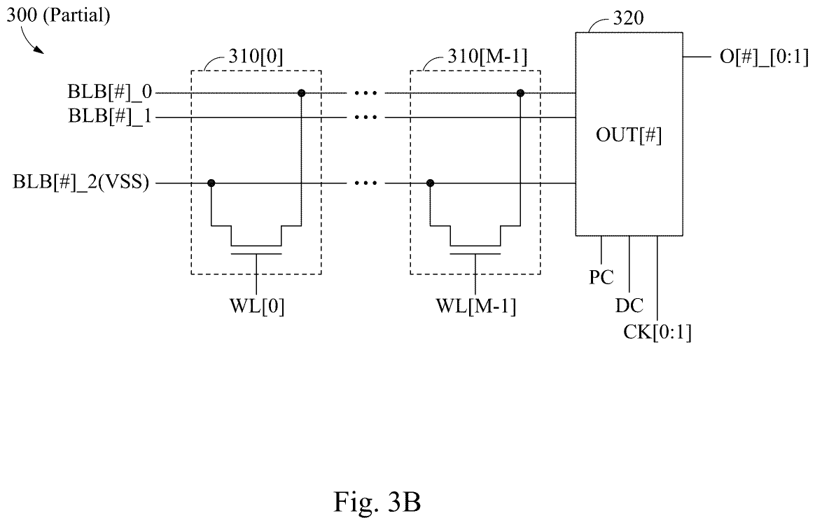

FIG. 2A is a schematic diagram of a memory cell 210 in association with a set of bit lines Net[0]~Net[N−1], in accordance with some embodiments. In some embodiments, memory cell 210 corresponds to a memory cell MC of memory device 100 in FIG. 1 and corresponds to a ROM memory cell. In FIG. 2A, N conductive lines are configured as N bit lines Net[0]~Net[N−1], and another conductive line is configured as a word line WL. In this example, memory cell 210 includes a transistor 212 that is an n-type transistor as a non-limiting example. In one or more other examples, a p-type transistor is usable as transistor 212.

In FIG. 2A, transistor 212 includes two drain/source terminals 212a and 212b and a gate terminal 212c. In some embodiments, gate terminal 212c of transistor 212 is electrically coupled to word line WL (e.g., one of word lines WL[0] to WL[M−1] in FIG. 1, labeled as “WL” in FIG. 2A) and configured to receive a word line signal through word line WL. Moreover, in FIG. 2A, the set of bit lines Net[0]~Net[N−1] includes N bit lines and corresponds to one set of the plurality of sets of bit lines BL[0] to BL[L−1] in FIG. 1. In some embodiments, the two drain/source terminals 212a and 212b are electrically coupled to a same bit line or two bit lines of the N bit lines Net[0]~Net[N−1], and an electrical coupling relationship between the two drain/source terminals 212a and 212b and the set of bit lines Net[0]~Net[N−1] indicating an information state of memory cell 210. In some embodiments, each one of two drain/source terminals 212a and 212b is electrically coupled to only one bit line of the set of bit lines Net[0]~Net[N−1].

FIG. 2B is a simplified table 220 of candidate information states of memory cell 210 in FIG. 2A, in accordance with some embodiments. In table 220, the left column represents to which bit line the drain/source terminal 212a is electrically coupled; and the top row represents to which bit line the drain/source terminal 212b is electrically coupled. In some embodiments, the candidate information states of memory cell 210 are based on an electrical coupling relationship between the two drain/source terminals 212a and 212b and the set of N bit lines Net[0]~Net[N−1].

In table 220, table entries in area 222 correspond to N different occasions of the two drain/source terminals 212a and 212b electrically coupled to the same bit line of the corresponding set of N bit lines. In table 220, table entries in area 224 correspond to

$$\frac{1}{2} N ( N - 1 )$$

different pairs of bit lines of the set of N bit lines to which the two drain/source terminals 212a and 212b are electrically coupled. Moreover, in this example, drain/source terminal 212a being electrically coupled to a first bit line and drain/source terminal 212b being electrically coupled to a second bit line represent the same information state as drain/source terminal 212a being electrically coupled to the second bit line and drain/source terminal 212b being electrically coupled to the first bit line. As such, table entries in area 226 correspond to another

$$\frac{1}{2} N ( N - 1 )$$

different pairs of bit lines of the set of N bit lines that mirror the combinations represented by table entries in area 224 but correspond to the same

$$\frac{1}{2} N ( N - 1 )$$

information states. Accordingly, in this example,

$$\{ \frac{1}{2} N ( N - 1 ) + 1 \}$$

candidate information states are defined, which includes

$$\frac{1}{2} N ( N - 1 )$$

candidate information states corresponding to electrically coupling to

$$\frac{1}{2} N ( N - 1 )$$

different pairs of bit lines of the corresponding set of N bit lines (e.g., table entries in areas 224 and 226) and one candidate information state corresponding to N different occasions of electrically coupling to the same bit line of the corresponding set of N bit lines (e.g., table entries in area 222). In this example, the

$$I = \{ \frac{1}{2} N ( N - 1 ) + 1 \}$$

candidate information states of memory cell 210 are usable to represent a value of K=┌log₂ I┐ bits.

FIG. 2C includes schematic diagrams 231-239 of memory cell 210 in FIG. 2A with various electrical coupling settings, in accordance with some embodiments. In this example, a memory cell (e.g., memory cell 210 with N set to three (3), not labeled in FIG. 2C) is configured in association with a set of three bit lines BLB0, BLB1, and BLB2. In FIG. 2C, as a non-limiting example, bit line BLB2 is configured to carry a lower supply voltage (denoted as VSS in this disclosure), and bit line BLB2 is therefore labeled as “(VSS)” in parentheses in FIG. 2C. In this disclosure, a lower supply voltage VSS has a lower voltage level than that of a higher supply voltage (denoted as VDD in this disclosure) of the memory device. In some embodiments, the lower supply voltage VSS corresponds to (or is replaceable by) a ground reference voltage. In some embodiments, the lower supply voltage VSS or the ground reference voltage represents logic ‘0’, and the higher supply voltage VDD represents logic ‘1’.

In FIG. 2C, schematic diagram 231 includes two drain/source terminals 212a and 212b of transistor 212 both electrically coupled to bit line BLB0; schematic diagram 232 includes drain/source terminal 212a electrically coupled to bit line BLB0 and drain/source terminal 212b electrically coupled to bit line BLB1; and schematic diagram 233 includes drain/source terminal 212a electrically coupled to bit line BLB0 and drain/source terminal 212b electrically coupled to bit line BLB2(VSS). In FIG. 2C, schematic diagram 234 includes drain/source terminal 212a electrically coupled to bit line BLB1 and drain/source terminal 212b electrically coupled to bit line BLB0; schematic diagram 235 includes two drain/source terminals 212a and 212b of transistor 212 both electrically coupled to bit line BLB1; and schematic diagram 236 includes drain/source terminal 212a electrically coupled to bit line BLB1 and drain/source terminal 212b electrically coupled to bit line BLB2(VSS). Also, in FIG. 2C, schematic diagram 237 includes drain/source terminal 212a electrically coupled to bit line BLB2(VSS) and drain/source terminal 212b electrically coupled to bit line BLB0; schematic diagram 238 includes drain/source terminal 212a electrically coupled to bit line BLB2(VSS) and drain/source terminal 212b electrically coupled to bit line BLB1; and schematic diagram 239 includes two drain/source terminals 212a and 212b of transistor 212 both electrically coupled to bit line BLB2(VSS).

FIG. 2D is a table 240 of candidate information states summarizing various electrical coupling settings in FIG. 2C, in accordance with some embodiments. In table 240, the left column represents to which bit line among bit lines BLB0, BLB1, and BLB2 (labeled as “(VSS)”) drain/source terminal 212a is electrically coupled; and the top row represents to which bit line among bit lines BLB0, BLB1, and BLB2 (labeled as “(VSS)”) drain/source terminal 212b is electrically coupled. In some embodiments, the candidate information states of memory cell 210 in FIGS. 2C and 2D correspond to the example in FIGS. 2A and 2B with N set to three (3).

In table 240, based on two drain/source terminals 212a and 212b electrically coupled to the same bit line (e.g. corresponding to the examples in schematic diagrams 231, 235, and 237), the memory cell has an information state of ‘0’. Based on two drain/source terminals 212a and 212b electrically coupled to bit lines BLB0 and BLB1 (e.g. corresponding to the examples in schematic diagrams 232 and 234), the memory cell has an information state of ‘a’. Based on two drain/source terminals 212a and 212b electrically coupled to bit lines BLB0 and BLB2(VSS) (e.g. corresponding to the examples in schematic diagrams 233 and 237), the memory cell has an information state of ‘b’. Also, based on two drain/source terminals 212a and 212b electrically coupled to bit lines BLB1 and BLB2(VSS) (e.g. corresponding to the examples in schematic diagrams 236 and 238), the memory cell has an information state of ‘b’. In this example, candidate information states {0, a, b, c} represent four (4) different data values. In some embodiments, candidate information states {0, a, b, c} represent binary values of {0b00, 0b01, 0b10, 0b11}. In this example, a memory cell in conjunction with three bit lines (e.g., N=3) is capable of recording a binary value of 2 bits.

According to one or more embodiments of the present disclosure, the candidate information states of a memory cell are defined based on the theoretical limit of the electrical coupling relationship using N bit lines. In some embodiments, for a configuration based on N bit lines for each column of memory cells, a reading cycle takes (N−1) reading stages. A decoder is configured to convert the sensed output signal into binary data. In some examples based on one or more embodiments of the present disclosure, the information density is increased by 100% for N=3 (with respect to one or more other designs). In some examples based on one or more embodiments of the present disclosure, the die area is reduced by 50% for N=3 (with respect to one or more other designs for storing the same volume of information).

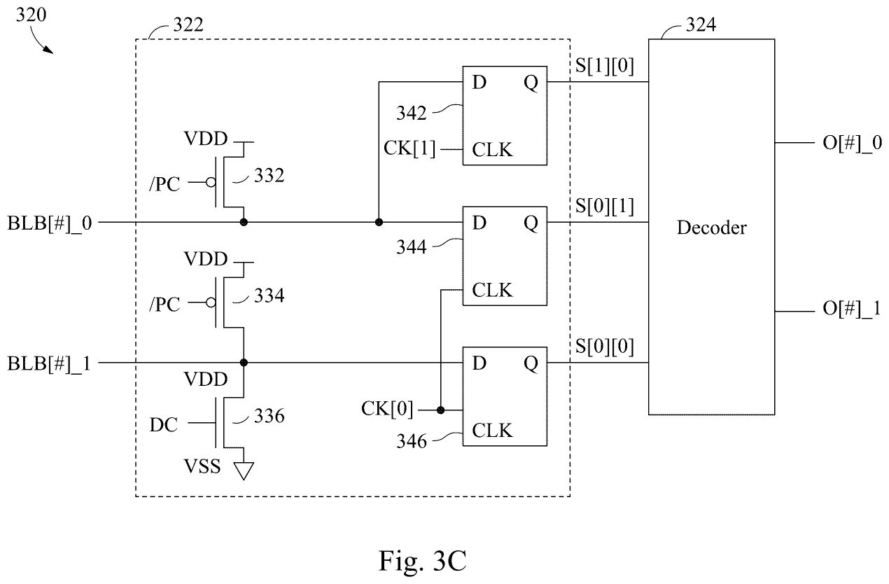

FIG. 3A is a schematic block diagram of a memory device 300 based on a first output circuitry configuration, in accordance with some embodiments. In some embodiments, memory device 300 corresponds to an implementation based on memory device 100 in FIG. 1 and the memory cell example in FIG. 2A. Accordingly, components in FIG. 3A that are the same or similar to those in FIG. 1 are given the same reference numbers or reference labels, and description thereof is simplified or omitted.

Compared to memory device 100 in FIG. 1, the memory cells MC are ROM memory cells, and memory device 300 in FIG. 3A includes an output circuitry 124A in place of input/output circuitry 124, and output circuitry 124A includes L portions (denoted as “O[0]-O[L−1] in FIG. 3A). In this example, each portion of output circuitry 124A is electrically coupled to a corresponding set of bit lines and configured to output a corresponding subset of decoded binary data (labeled as O[0]-O[L−1] outputs for each set of bit lines, and collectively O[0:P−1] outputs in FIG. 3A). In this example, each one of O[0]-O[L−1] outputs has K bits, where

$$P = L \times K , K = ⌈ {log}_{2} I ⌉ , and I = \{ \frac{1}{2} N ( N - 1 ) + 1 \} .$$

FIG. 3B is a schematic diagram of a portion of memory device 300 in FIG. 3A (labeled as “300 Partial”), including a column of memory cells 310[0]-310[M−1] in association with a set of bit lines BLB[#]_0, BLB[#]_1, and BLB[#]_2, and including a portion of an output circuitry 320 (labeled as “O[#]”) of memory device 300 electrically coupled to the set of bit lines, in accordance with some embodiments. In this example, ‘#’ in FIGS. 3A and 3B corresponds to a number from 0 to (L−1).

In this non-limiting example, the column of memory cells 310[0]-310[M−1] is configured based on the example of FIGS. 2C and 2D in conjunction with a set of three bit lines (e.g., N is set to three). In this non-limiting example, bit line BLB[#]_0 corresponds to bit line BLB0, BLB[#]_1 corresponds to bit line BLB1, and BLB[#]_2 corresponds to bit line BLB2 in FIG. 2C. In this non-limiting example, bit line BLB[#]_2 is configured to carry the lower supply voltage (e.g., ground level VSS), and bit line BLB[#]_2 is labeled as “BLB[#]_2 (VSS)” in FIG. 3B. Moreover, in FIG. 3B, the portion of output circuitry 320 is configured to receive a pre-charge signal (labeled as “PC”), a discharge signal (labeled as “DC”), and two sampling clock signals (labeled as CK[0:1]). In FIG. 3B, the portion of output circuitry 320 is configured to output a decoded binary data (labeled as O[#]_[0:1]).

FIG. 3C is a schematic diagram of the portion of the output circuitry 320 of the memory device in FIG. 3B, in accordance with some embodiments. In some embodiments, the schematic diagram in FIG. 3C is a simplified schematic diagram, and certain components of output circuitry 320 are simplified or omitted without compromising the clarity of the disclosure. Also, components in FIG. 3C that are the same or similar to those in FIG. 3B are given the same reference labels or reference numbers, and description thereof is simplified or omitted.

In FIG. 3C, the portion of the output circuitry 320 includes a sense circuitry 322 and a decoder 324 (or a partial of the decoder 324). In FIG. 3C, sense circuitry 322 includes a first pre-charge transistor 332 electrically coupled between a first power node carrying the higher supply voltage VDD and bit line BLB[#]_0, a second pre-charge transistor 334 electrically coupled between the first power node carrying the higher supply voltage VDD and bit line BLB[#]_1, and a discharge transistor 336 electrically coupled between a second power node carrying the lower supply voltage VSS and bit line BLB[#]_1. In this example, the gate terminals of pre-charge transistors 332 and 334 are configured to receive a pre-charge bar signal (labeled as “/PC”) that is a logically complementary signal of pre-charge signal PC, and the gate terminal of discharge transistor 336 is configured to receive discharge signal DC.

Moreover, in FIG. 3C, sense circuitry 322 further includes two single-bit data sampling devices 342 and 344 having data input nodes (labeled as ‘D’ therein) electrically coupled to bit line BLB[#]_0, and a single-bit data sampling device 346 having a data input node (labeled as ‘D’ therein) electrically coupled to bit line BLB[#]_1. In FIG. 3C, single-bit data sampling devices 346, 344, and 342 have output nodes (labeled as ‘Q’ therein) configured to provide output signals S[0][0], S[0][1], and S[1][0] constituting a three-bit output data of sense circuitry 322. In some embodiments, each one of the single-bit data sampling devices 342, 344, and 346 corresponds to a flip-flop or a latch. In this example, sampling clock signal CK[0] is applied to clock or enable nodes (labeled as ‘CLK’ therein) of single-bit data sampling devices 344 and 346, and sampling clock signal CK[1] is applied to a clock or enable node of single-bit data sampling device 342. In this example, decoder 324 is configured to convert the output signals S[0][0], S[0][1], and S[1][0] from sense circuitry 322 into binary data O[#]_0 and O[#]_1 as output.

In some embodiments, the portion of output circuitry 320 is configured to detect the electrical coupling relationship between the two drain/source terminals of an activated memory cell (activated by a corresponding word line) and the set of three (3) bit lines based on two (2) reading stages.

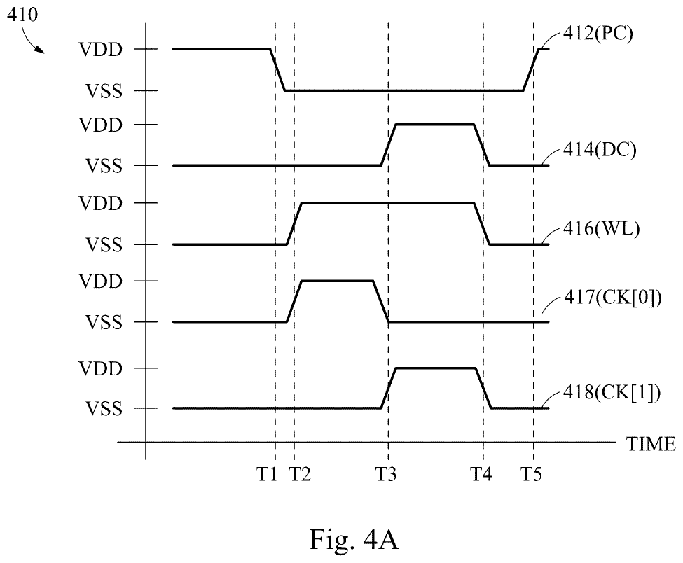

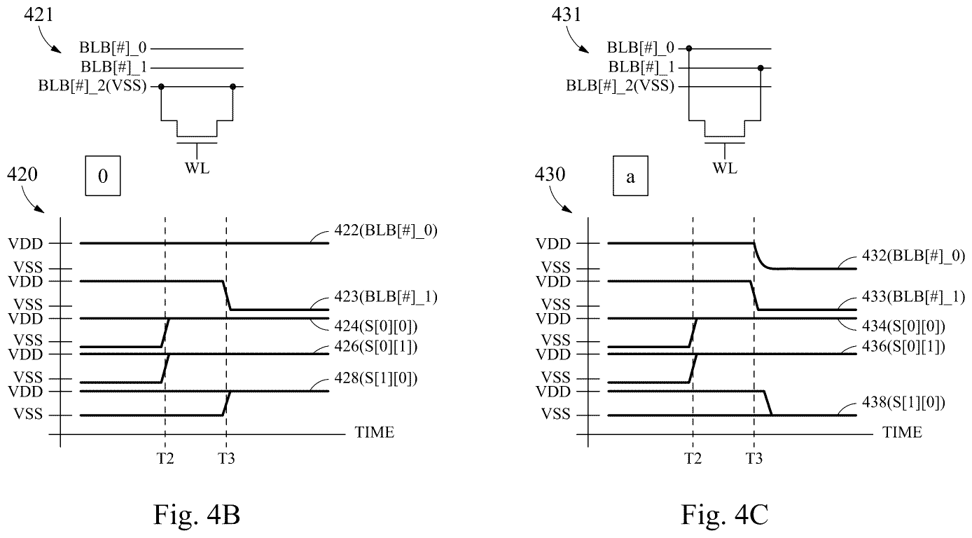

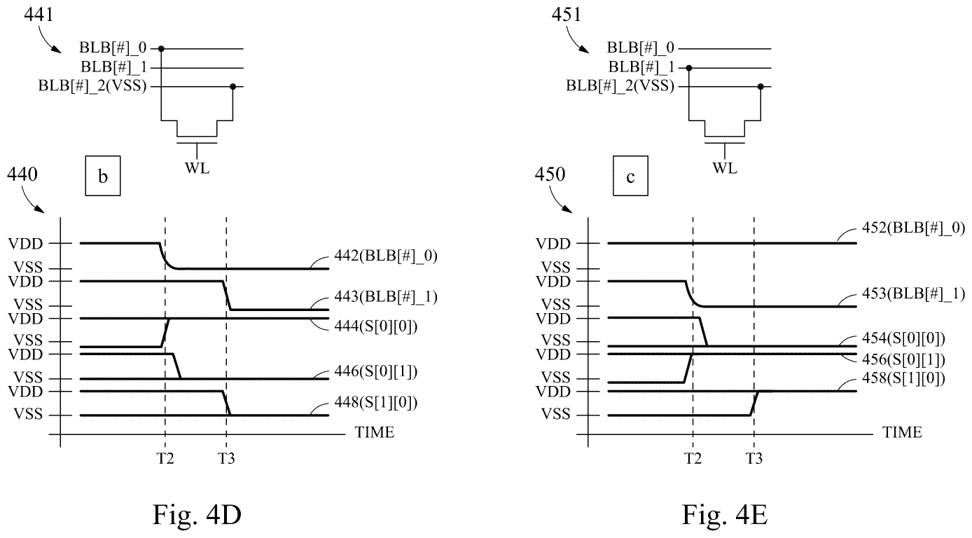

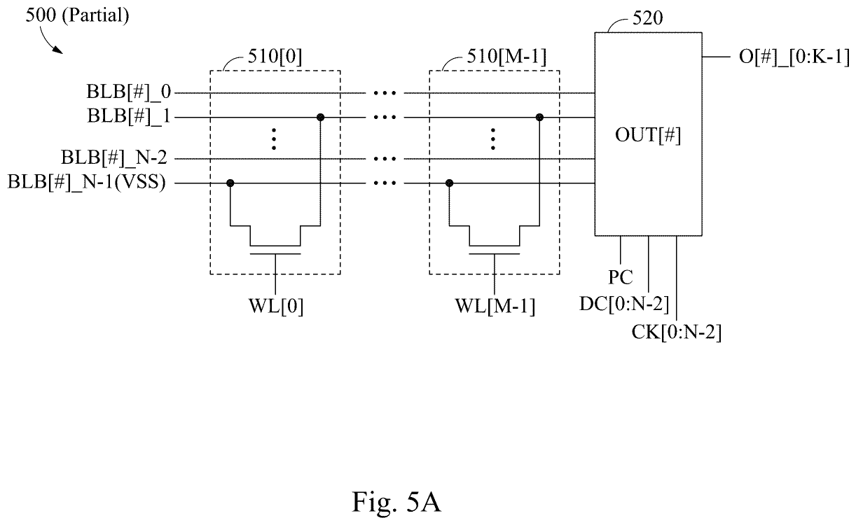

FIG. 4A is a timing diagram 410 of various control signals for controlling a reading cycle of sense circuitry 322 in FIG. 3C, in accordance with some embodiments. In FIG. 4A, the vertical axis represents the voltage levels of the signals, and the horizontal axis represents time. In FIG. 4A, timing diagram 410 includes curve 412 representing the voltage level of the pre-charge signal PC in FIG. 3B that is the logically complementary signal of the pre-charge bar signal/PC in FIG. 3C. In FIG. 4A, timing diagram 410 further includes curve 414 representing the voltage level of the discharge signal DC in FIG. 3C, curve 416 representing the voltage level of a word line signal WL on one of the word line WL[0]-WL[M−1] in FIG. 3C, curve 417 representing the voltage level of the sampling clock signal CK[0] in FIG. 3C, and curve 418 representing the voltage level of the sampling clock signal CK[1] in FIG. 3C.

In some embodiments, sense circuitry 322 detects the information state of an activated memory cell based on two (2) reading stages controlled by the signals described with respect to the example in timing diagram 410. In FIG. 4A, prior to time T1, the pre-charge signal PC is at VDD, indicating that the pre-charge bar signal/PC is at VSS to turn on pre-charge transistors 332 and 334 in FIG. 3C. As such, prior to time T1, bit line BLB[#]_0 and bit line BLB[#]_1 are pre-charged to VDD. Next, at time T1, the pre-charge signal PC transitions from VDD to VSS, indicating that the pre-charge bar signal/PC transitions from VSS to VDD to turn off pre-charge transistors 332 and 334 in FIG. 3C.

At time T2, the corresponding word line WL transitions from VSS to VDD to turn on the transistor of the memory cell to be accessed. At time T2, sampling clock signal CK[0] also transitions from VSS to VDD to enable data sampling functionality of single-bit data sampling devices 344 and 346. In this example, a first reading stage corresponds to a sensing operation performed from time T2 up to time T3.

At time T3, discharge signal DC transitions from VSS to VDD to turn on discharge transistor 336 in FIG. 3C. As such, at time T3, bit line BLB[#]_1 is discharged to VSS. Also, at time T3, sampling clock signal CK[0] transitions from VDD to VSS to disable data sampling functionality of single-bit data sampling devices 344 and 346, and sampling clock signal CK[1] transitions from VSS to VDD to enable data sampling functionality of single-bit data sampling device 342. In this example, a second reading stage corresponds to a sensing operation performed from time T3 up to time T4.

At time T4, discharge signal DC transitions from VDD to VSS to turn off discharge transistor 336, and the corresponding word line WL transitions from VDD to VSS to turn off the transistor of the memory cell to be accessed. Also, at time T4, sampling clock signal CK[1] transitions from VDD to VSS to disable data sampling functionality of single-bit data sampling device 342. Therefore, after time T4, the single-bit data sampling devices 342, 344, and 346 no longer respond to the voltage levels of bit line BLB[#]_0 and bit line BLB[#]_1. Finally, at time T5, the pre-charge signal PC transitions from VSS to VDD, indicating that the pre-charge bar signal/PC transitions from VDD to VSS to turn on pre-charge transistors 332 and 334. Therefore, after time T5, bit line BLB[#]_0 and bit line BLB[#]_1 are once again pre-charged to VDD and ready for a next reading cycle.

FIG. 4B is a timing diagram 420 of signals at various terminals of the sense circuitry 322 in FIG. 3C based on detecting the activated memory cell having an information state corresponding to information state ‘0’ in FIG. 2C (also indicated by a label ‘0’ in FIG. 4B), in accordance with some embodiments. FIG. 4B also includes a schematic diagram 421 of the activated memory cell corresponding to the two drain/source terminals of the memory cell being electrically coupled to bit line BLB[#]_2 (VSS). In this example, schematic diagram 421 corresponds to schematic diagram 239 in FIG. 2C, and detailed description thereof is omitted.

In timing diagram 420, the vertical axis represents voltage levels of the signals, and the horizontal axis represents time. In FIG. 4B, timing diagram 420 includes curve 422 representing the voltage level of bit line BLB[#]_0 in FIG. 3C and schematic diagram 421, and curve 423 representing the voltage level of bit line BLB[#]_1 in FIG. 3C and schematic diagram 421. In FIG. 4B, timing diagram 420 further includes curve 424 representing the voltage level of the output signal S[0][0] in FIG. 3C, curve 426 representing the voltage level of the output signal S[0][1] in FIG. 3C, and curve 428 representing the voltage level of the output signal S[1][0] in FIG. 3C. Moreover, in timing diagram 420, time T2 and time T3 correspond to time T2 and time T3 in FIG. 4A.

In FIG. 4B, prior to time T2, bit line BLB[#]_0 and bit line BLB[#]_1 are pre-charged to VDD. Also, prior to time T2, output signals S[0][0], S[0][1], and S[1][0] keep the sampled data as represented by either VDD or VDD from a previous reading cycle. At time T2, as the word line WL transitions from VSS to VDD and sampling clock signal CK[0] transitions from VSS to VDD, single-bit data sampling devices 346 and 344 are enabled, and the voltage levels at output signals S[0][0] and S[0][1] are updated based on the voltage levels at bit line BLB[#]_0 and bit line BLB[#]_1. Because bit line BLB[#]_0 and bit line BLB[#]_1 are not electrically coupled to a path carrying VSS, bit line BLB[#]_0 and bit line BLB[#]_1 remain at VDD, and output signals S[0][0] and S[0][1] are at VDD as well.

In FIG. 4B, at time T3, as sampling clock signal CK[0] transitions from VDD to VSS, single-bit data sampling devices 346 and 344 are disabled. Also, at time T3, as sampling clock signal CK[1] transitions from VSS to VDD, single-bit data sampling device 342 is enabled, and the voltage level at output signal S[1][0] is updated based on the voltage level at bit line BLB[#]_0. At time T3, discharge signal DC transitions from VSS to VDD to discharge bit line BLB[#]_1 to VSS. However, bit line BLB[#]_0 is not electrically coupled to a path carrying VSS, and bit line BLB[#]_0 remains at VDD and output signal S[1][0] is at VDD as well. Accordingly, after time T3, output signals S[0][0], S[0][1], and S[1][0] have voltage levels of VDD, VDD, and VDD representing the active memory cell has information state ‘0.’

FIG. 4C is a timing diagram 430 of signals at various terminals of the sense circuitry 322 in FIG. 3C based on detecting the activated memory cell having an information state corresponding to information state ‘a’ in FIG. 2C (also indicated by a label ‘a’ in FIG. 4C), in accordance with some embodiments. FIG. 4C also includes a schematic diagram 431 of the activated memory cell and corresponding to schematic diagram 232 in FIG. 2C, and detailed description thereof is omitted.

In timing diagram 430, the vertical axis represents voltage levels of the signals, and the horizontal axis represents time. In FIG. 4C, timing diagram 430 includes curve 432 representing the voltage level of bit line BLB[#]_0 in FIG. 3C and schematic diagram 431, and curve 433 representing the voltage level of bit line BLB[#]_1 in FIG. 3C and schematic diagram 431. In FIG. 4C, timing diagram 430 further includes curve 434 representing the voltage level of the output signal S[0][0] in FIG. 3C, curve 436 representing the voltage level of the output signal S[0][1] in FIG. 3C, and curve 438 representing the voltage level of the output signal S[1][0] in FIG. 3C. Moreover, in timing diagram 430, time T2 and time T3 correspond to time T2 and time T3 in FIG. 4A.

In FIG. 4C, prior to time T3, bit line BLB[#]_0 and bit line BLB[#]_1 are pre-charged to VDD. Also, prior to time T2, output signals S[0][0], S[0][1], and S[1][0] keep the sampled data as represented by either VDD or VDD from a previous reading cycle. At time T2, as the word line WL transitions from VSS to VDD and sampling clock signal CK[0] transitions from VSS to VDD, single-bit data sampling devices 346 and 344 are enabled, and the voltage levels at output signals S[0][0] and S[0][1] are updated based on the voltage levels at bit line BLB[#]_0 and bit line BLB[#]_1. Although bit line BLB[#]_0 and bit line BLB[#]_1 are electrically coupled together through the transistor of the activated memory cell, bit line BLB[#]_0 and bit line BLB[#]_1 are not electrically coupled to a path carrying VSS. As such, bit line BLB[#]_0 and bit line BLB[#]_1 remain at VDD, and output signals S[0][0] and S[0][1] are at VDD as well.

In FIG. 4C, at time T3, as sampling clock signal CK[0] transitions from VDD to VSS, single-bit data sampling devices 346 and 344 are disabled. Also, at time T3, as sampling clock signal CK[1] transitions from VSS to VDD, single-bit data sampling device 342 is enabled, and the voltage level at output signal S[1][0] is updated based on the voltage level at bit line BLB[#]_0. At time T3, discharge signal DC transitions from VSS to VDD to discharge bit line BLB[#]_1 to VSS. Because bit line BLB[#]_0 and bit line BLB[#]_1 are electrically coupled together through the transistor of the activated memory cell, bit line BLB[#]_0 is discharged to VSS, and output signal S[1][0] is at VSS. Accordingly, after time T3, output signals S[0][0], S[0][1], and S[1][0] have voltage levels of VDD, VDD, and VSS representing the active memory cell has information state ‘a.’

FIG. 4D is a timing diagram 440 of signals at various terminals of the sense circuitry 322 in FIG. 3C based on detecting the activated memory cell having an information state corresponding to information state ‘b’ in FIG. 2C (also indicated by a label ‘b’ in FIG. 4D), in accordance with some embodiments. FIG. 4D also includes a schematic diagram 441 of the activated memory cell corresponding to schematic diagram 233 in FIG. 2C, and detailed description thereof is omitted.

In timing diagram 440, the vertical axis represents voltage levels of the signals, and the horizontal axis represents time. In FIG. 4D, timing diagram 440 includes curve 442 representing the voltage level of bit line BLB[#]_0 in FIG. 3C and schematic diagram 441, and curve 443 representing the voltage level of bit line BLB[#]_1 in FIG. 3C and schematic diagram 441. In FIG. 4D, timing diagram 440 further includes curve 444 representing the voltage level of the output signal S[0][0] in FIG. 3C, curve 446 representing the voltage level of the output signal S[0][1] in FIG. 3C, and curve 448 representing the voltage level of the output signal S[1][0] in FIG. 3C. Moreover, in timing diagram 440, time T2 and time T3 correspond to time T2 and time T3 in FIG. 4A.

In FIG. 4D, prior to time T3, bit line BLB[#]_0 and bit line BLB[#]_1 are pre-charged to VDD. Also, prior to time T2, output signals S[0][0], S[0][1], and S[1][0] keep the sampled data as represented by either VDD or VDD from a previous reading cycle. At time T2, as the word line WL transitions from VSS to VDD and sampling clock signal CK[0] transitions from VSS to VDD, single-bit data sampling devices 346 and 344 are enabled, and the voltage levels at output signals S[0][0] and S[0][1] are updated based on the voltage levels at bit line BLB[#]_0 and bit line BLB[#]_1. Because bit line BLB[#]_0 is electrically coupled to bit line BLB[#]_2 (VSS) through the transistor of the activated memory cell, bit line BLB[#]_0 is pull to VSS while BLB[#]_1 remains at VDD. As such, output signal S[0][0] is at VDD and S[0][1] is at VSS.

In FIG. 4D, at time T3, as sampling clock signal CK[0] transitions from VDD to VSS, single-bit data sampling devices 346 and 344 are disabled. Also, at time T3, as sampling clock signal CK[1] transitions from VSS to VDD, single-bit data sampling device 342 is enabled, and the voltage level at output signal S[1][0] is updated based on the voltage level at bit line BLB[#]_0. At time T3, discharge signal DC transitions from VSS to VDD to discharge bit line BLB[#]_1 to VSS. Because bit line BLB[#]_0 is electrically coupled to bit line BLB[#]_2 (VSS) through the transistor of the activated memory cell, bit line BLB[#]_0 remains at VSS, and output signal S[1][0] is at VSS. Accordingly, after time T3, output signals S[0][0], S[0][1], and S[1][0] have voltage levels of VDD, VSS, and VSS representing the active memory cell has information state ‘b.’

FIG. 4E is a timing diagram 450 of signals at various terminals of the sense circuitry 322 in FIG. 3C based on detecting the activated memory cell having an information state corresponding to information state ‘c’ in FIG. 2C (also indicated by a label ‘c’ in FIG. 4E), in accordance with some embodiments. FIG. 4E also includes a schematic diagram 451 of the activated memory cell corresponding to schematic diagram 236 in FIG. 2C, and detailed description thereof is omitted.

In timing diagram 450, the vertical axis represents voltage levels of the signals, and the horizontal axis represents time. In FIG. 4E, timing diagram 450 includes curve 452 representing the voltage level of bit line BLB[#]_0 in FIG. 3C and schematic diagram 451, and curve 453 representing the voltage level of bit line BLB[#]_1 in FIG. 3C and schematic diagram 451. In FIG. 4E, timing diagram 450 further includes curve 454 representing the voltage level of the output signal S[0][0] in FIG. 3C, curve 456 representing the voltage level of the output signal S[0][1] in FIG. 3C, and curve 458 representing the voltage level of the output signal S[1][0] in FIG. 3C. Moreover, in timing diagram 450, time T2 and time T3 correspond to time T2 and time T3 in FIG. 4A.

In FIG. 4E, prior to time T3, bit line BLB[#]_0 and bit line BLB[#]_1 are pre-charged to VDD. Also, prior to time T2, output signals S[0][0], S[0][1], and S[1][0] keep the sampled data as represented by either VDD or VDD from a previous reading cycle. At time T2, as the word line WL transitions from VSS to VDD and sampling clock signal CK[0] transitions from VSS to VDD, single-bit data sampling devices 346 and 344 are enabled, and the voltage levels at output signals S[0][0] and S[0][1] are updated based on the voltage levels at bit line BLB[#]_0 and bit line BLB[#]_1. Because bit line BLB[#]_1 is electrically coupled to bit line BLB[#]_2 (VSS) through the transistor of the activated memory cell, bit line BLB[#]_1 is pull to VSS while BLB[#]_0 remains at VDD. As such, output signal S[0][0] is at VSS and S[0][1] is at VDD.

In FIG. 4E, at time T3, as sampling clock signal CK[0] transitions from VDD to VSS, single-bit data sampling devices 346 and 344 are disabled. Also, at time T3, as sampling clock signal CK[1] transitions from VSS to VDD, single-bit data sampling device 342 is enabled, and the voltage level at output signal S[1][0] is updated based on the voltage level at bit line BLB[#]_0. At time T3, discharge signal DC transitions from VSS to VDD to discharge bit line BLB[#]_1 to VSS. Because bit line BLB[#]_0 is not electrically coupled to bit line BLB[#]_0 or any path that carries VSS, bit line BLB[#]_0 remains at VDD, and output signal S[1][0] is at VDD. Accordingly, after time T3, output signals S[0][0], S[0][1], and S[1][0] have voltage levels of VSS, VDD, and VDD representing the active memory cell has information state ‘c.’

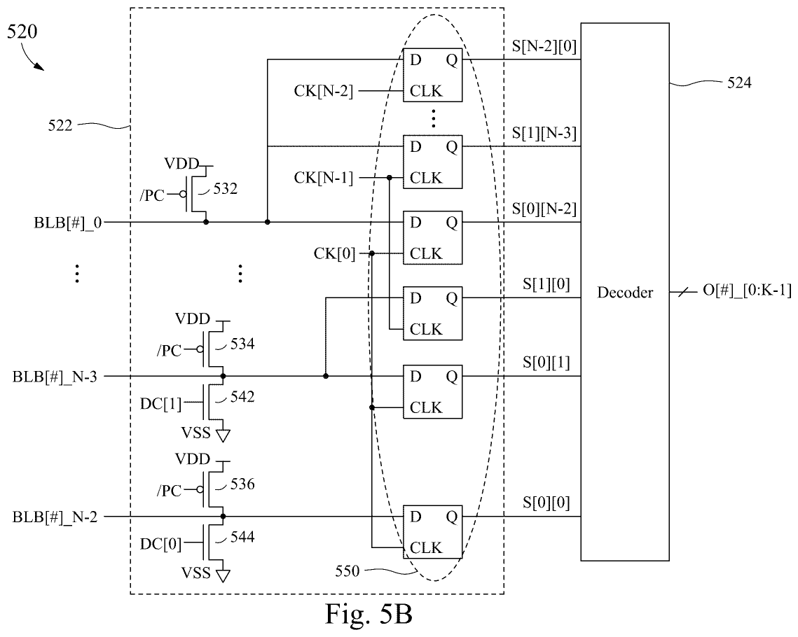

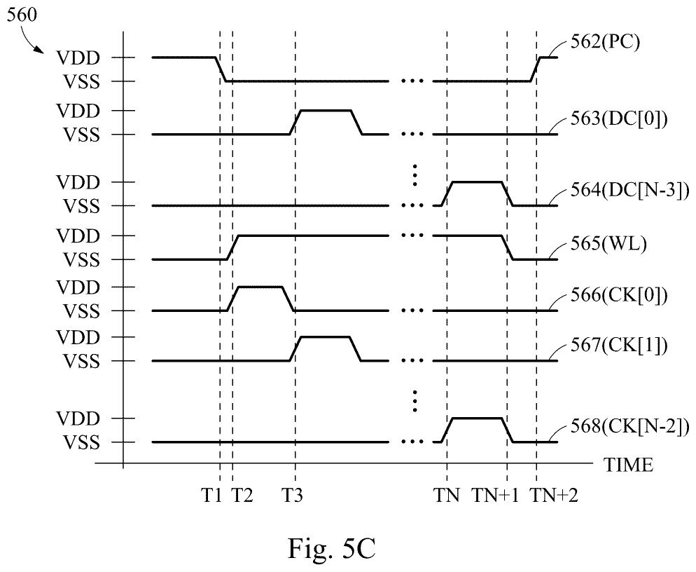

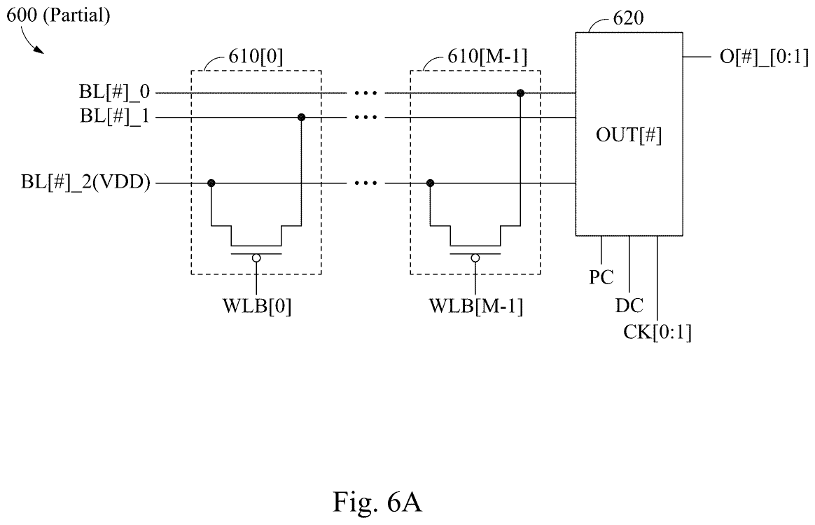

FIG. 5A is a schematic diagram of a portion of memory device 500 (labeled as “500 (Partial)”), including a column of memory cells 510[0]-510[M−1] in association with a set of bit lines BLB[#]_0-BLB[#]_N−1, and including a portion of an output circuitry 520 of memory device 500 electrically coupled to the set of bit lines, in accordance with some embodiments. In some embodiments, memory device 500 is implemented based on memory device 300 in FIG. 3A, and ‘#’ in FIG. 5A corresponds to a number from 0 to (L−1). In some embodiments, the portion of memory device 500 in FIG. 5A is based on a generalization of the example in FIG. 3B, with N being an integer equal to or greater than three (3).

In this non-limiting example, the column of memory cells 510[0]-510[M−1] is configured based on the example of FIGS. 2C and 2D in conjunction with a set of N bit lines. In this non-limiting example, bit line BLB[#]_N−1 is configured to carry a lower supply voltage, and bit line BLB[#]_N−1 is labeled as “BLB[#]_N−1 (VSS)” in FIG. 5A. Moreover, in FIG. 5A, the portion of output circuitry 520 is configured to receive a pre-charge signal (labeled as “PC”), a set of discharge signals (labeled as “DC[0:N−2]”), and a set of sampling clock signals (labeled as CK[0:N−2]). In FIG. 5A, the portion of output circuitry 520 is configured to output decoded binary data (labeled as O[#]_[0:K−1], where K=┘log₂ I┌, and

$$I = \{ \frac{1}{2} N ( N - 1 ) + 1 \} ) .$$

FIG. 5B is a schematic diagram of the portion of the output circuitry 520 of the memory device in FIG. 5A, in accordance with some embodiments. In some embodiments, the schematic diagram in FIG. 5B is a simplified schematic diagram, and certain components of output circuitry 520 are simplified or omitted without compromising the clarity of the disclosure. Also, components in FIG. 5B that are the same or similar to those in FIG. 5A are given the same reference labels or reference numbers, and description thereof is simplified or omitted. In some embodiments, the portion of the output circuitry 520 in FIG. 5B is based on a generalization of the example in FIG. 3C, with N being an integer equal to or greater than three (3).

In FIG. 5B, the portion of the output circuitry 520 includes a sense circuitry 522 and a decoder 524 (or a partial of the decoder 524). In FIG. 5B, sense circuitry 522 includes (N−1) pre-charge transistors 532, 534, and 536 electrically coupled between a first power node carrying a first supply voltage (e.g., VDD) and corresponding ones of a corresponding set of N bit lines (e.g., BLB[#]_0 to BLB[#]_N−1). In this example, the gate terminals of (N−1) pre-charge transistors 532, 534, and 536 are configured to receive a pre-charge bar signal (labeled as “/PC”) that is a logically complementary signal of pre-charge signal PC. Also, sense circuitry 522 includes (N−2) discharge transistors 542 and 544 electrically coupled between a second power node carrying a second supply voltage (e.g., VSS) and second one through (N−1)-th one of the corresponding set of N bit lines (e.g., BLB[#]_1 to BLB[#]_N−2). In this example, an N-th bit line (e.g., BLB[#]_N−1) of the corresponding set of N bit lines is configured to carry the second supply voltage (e.g., VSS) as indicated in FIG. 5A. In this example, for each index i ranging from 2 to (N−1), the gate terminal of a discharge transistor corresponding to the (N−i+1)-th bit line is configured to receive an (i−1)-th discharging signal (labeled as DC[i−2], e.g., discharge transistors corresponding to BLB[#]_1-BLB[#]_N−2 are electrically coupled to DC[N−3]-DC[0]).

Moreover, sense circuitry 522 includes

$$\frac{1}{2} N ( N - 1 )$$

single-bit data sampling devices 550, which includes, for each index i ranging from 1 to (N−1), (N−i) single-bit data sampling device(s) having data input node(s) (labeled as ‘D’ therein) electrically coupled to i-th one of the corresponding set of N bit lines. In this example, for each index i ranging from 1 to (N−1), an i-th sampling clock signal (e.g., CK[i−1]) of the (N−1) sampling clock signals is applied to clock or enable node(s) (labeled as ‘CLK’ therein) of (N−i) single-bit data sampling devices that are electrically coupled to a first bit line through an (N−i)-th bit line of the corresponding set of N bit lines. In this example, for each index i ranging from 1 to (N−1), (N−i) single-bit data sampling device(s) are enabled by sampling clock signal CK[i−1] and are configured to provide output signals denoted as S[i][0:N−2]. In some embodiments, each one of the single-bit data sampling devices 550 corresponds to a flip-flop or a latch. In this example, decoder 524 is configured to convert the output signals from sense circuitry 522 into binary data O[#]_[0:K−1] as output.

In some embodiments, the portion of output circuitry 520 is configured to detect the electrical coupling relationship between the two drain/source terminals of an activated memory cell (activated by a corresponding word line) and the set of N bit lines based on (N−1) reading stages.

FIG. 5C is a timing diagram 560 of various control signals for controlling a reading cycle of sense circuitry 522 in FIG. 5B, in accordance with some embodiments. In FIG. 5C, the vertical axis represents voltage levels of the signals, and the horizontal axis represents time. In FIG. 5C, timing diagram 560 includes curve 562 representing the voltage level of the pre-charge signal PC in FIG. 5A that is the logically complementary signal of the pre-charge bar signal/PC in FIG. 5B. In FIG. 5C, timing diagram 560 further includes curve 563 and curve 564 representing the voltage levels of the discharge signal DC[0] and DC[N−3], and curve 565 representing the voltage level of a word line signal WL on one of the word line WL[0]-WL[M−1] in FIG. 5A. Also, timing diagram 560 further includes curve 566, curve 567, and curve 568 representing the voltage level of the sampling clock signal CK[0], CK[1], and CK[N−2].

In some embodiments, sense circuitry 522 detects the information state of an activated memory cell based on N−1 reading stages controlled by the signals described with respect to the example in the timing diagram 560. In some embodiments, timing diagram 560 in FIG. 5C is based on a generalization of the example in FIG. 4A, with N being an integer equal to or greater than three (3).

In FIG. 5A, prior to time T1, the pre-charge signal PC is at VDD, indicating that the pre-charge bar signal/PC is at VSS to turn on the (N−1) pre-charge transistors in FIG. 5A. As such, prior to time T1, N−1 bit lines bit line BLB[#]_0-bit line BLB[#]_N−2 are pre-charged to VDD. Next, at time T1, the pre-charge signal PC transitions from VDD to VSS, indicating that the pre-charge bar signal/PC transitions from VSS to VDD to turn off the (N−1) pre-charge transistors.

At time T2, the corresponding word line WL transitions from VSS to VDD to turn on the transistor of the memory cell to be accessed. At time T2, sampling clock signal CK[0] also transitions from VSS to VDD to enable data sampling functionality of a first set of single-bit data sampling devices (e.g., providing output signals S[0][0:N−2]). In this example, a first reading stage corresponds to a sensing operation performed from time T2 up to time T3.

At time T3, discharge signal DC[0] transitions from VSS to VDD to turn on discharge transistor 544 in FIG. 5B. As such, at time T3, bit line BLB[#]_N−2 is discharged to VSS. Also, at time T3, sampling clock signal CK[0] transitions from VDD to VSS and sampling clock signal CK[1] transitions from VSS to VDD to enable data sampling functionality of a second set of single-bit data sampling devices (e.g., providing output signals S[1][0:N−3]). In this example, a second reading stage corresponds to a sensing operation performed starting at time T3.

Afterwords, the sampling clock signal CK[2:N−2] and the discharge signal DK[1:N−3] are sequentially set to VDD for the corresponding reading cycles. For example, at time TN, discharge signal DC[N−3] transitions from VSS to VDD to turn on the corresponding discharge transistor. As such, at time TN, bit line BLB[#]_1 is discharged to VSS. Also, at time TN, sampling clock signal CK[N−3] transitions from VDD to VSS and sampling clock signal CK[N−2] transitions from VSS to VDD to enable data sampling functionality of a single-bit data sampling device (e.g., providing output signals S[N−2][0]). In this example, an (N−1)-th reading stage corresponds to a sensing operation performed starting at time TN to time TN+1.

At time TN+1, discharge signal DC[N−3] transitions from VDD to VSS, and the corresponding word line WL transitions from VDD to VSS to turn off the transistor of the memory cell to be accessed. Also, at time TN+1, sampling clock signal CK[N−2] transitions from VDD to VSS to disable data sampling functionality of the single-bit data sampling device corresponding to providing output signals S[N−2][0]. After time TN+1, the single-bit data sampling devices 550 no longer respond to the voltage levels of bit line BLB[#]_0 to bit line BLB[#]_N−2. Finally, at time TN+2, the pre-charge signal PC transitions from VSS to VDD, indicating that the pre-charge bar signal/PC transitions from VDD to VSS to turn on the (N−1). Therefore, after time TN+2, the N−1 bit lines (bit line BLB[#]_0 to bit line BLB[#]_N−2) are once again pre-charged to VDD and ready for a next reading cycle.

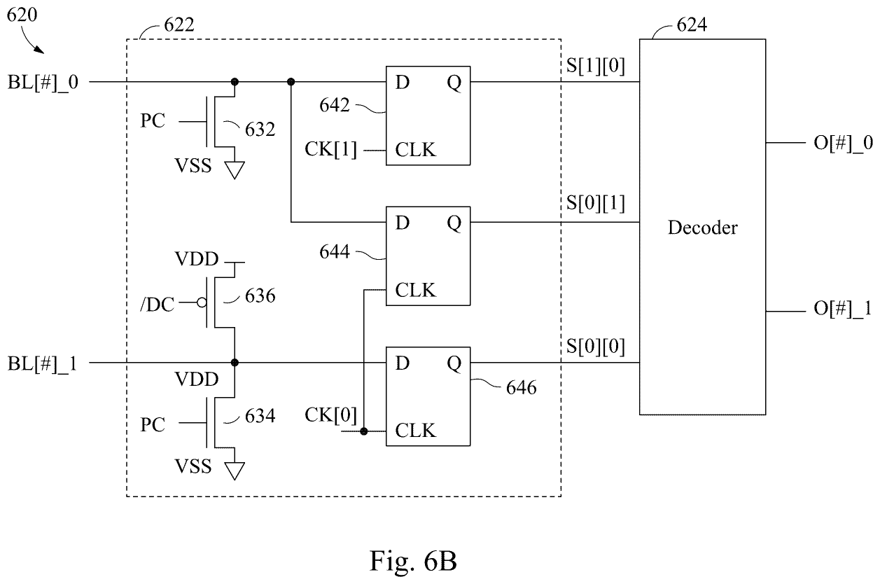

FIG. 6A is a schematic diagram of a portion of a memory device 600 (labeled as “600 #”), including a column of memory cells 610[0]-610[M−1] in association with a set of bit lines BL[#]_0, BL[#]_1, and BL[#]_2, and including a portion of the output circuitry 620 (denoted as “O[#]”) of memory device 600 electrically coupled to the set of bit lines, in accordance with some embodiments. In this example, ‘#’ in FIGS. 6A and 6B corresponds to a number from 0 to (L−1).

In this non-limiting example, the column of memory cells 610[0]-610[M−1] is configured based on the example of FIGS. 2C and 2D (with the modifications based on replacing the n-type transistors with p-type transistors) in conjunction with a set of three bit lines (e.g., N is set to three). As such, memory device 600 corresponds to a variation of memory device 300 based on including p-type transistors in the memory cells together with suitable adjustments to the polarities of various control signals of memory device 600. In this non-limiting example, bit line BL[#]_2 is configured to carry a higher supply voltage, and bit line BL[#]_2 is labeled as “BL[#]_2 (VDD)” in FIG. 6A. Moreover, in FIG. 6A, the portion of output circuitry 620 is configured to receive a pre-charge signal (labeled as “PC”), a discharge signal (labeled as “DC”), and two sampling clock signals (labeled as CK[0:1]). In FIG. 6A, the portion of output circuitry 620 is configured to output a decoded binary data (labeled as O[#]_[0:1]).

FIG. 6B is a schematic diagram of the portion of the output circuitry 620 of the memory device in FIG. 6A, in accordance with some embodiments. In some embodiments, the schematic diagram in FIG. 6B is a simplified schematic diagram, and certain components of output circuitry 620 are simplified or omitted without compromising the clarity of the disclosure. Also, components in FIG. 6B that are the same or similar to those in FIG. 6A are given the same reference labels or reference numbers, and description thereof is simplified or omitted.

In FIG. 6B, the portion of the output circuitry 620 includes a sense circuitry 622 and a decoder 624 (or a partial of the decoder 624). In some embodiments, sense circuitry 622 is based on a configuration similar to that of sense circuitry 322, with modifications such as swapping the types of transistors (e.g., n-type transistors to p-type transistors and vice versa) and swapping the polarities of signals and supply voltages.

For example, in FIG. 6B, sense circuitry 622 includes a first pre-charge transistor 632 electrically coupled between a first power node carrying the lower supply voltage VSS and bit line BL[#]_0, a second pre-charge transistor 634 electrically coupled between the first power node carrying the lower supply voltage VSS and bit line BL[#]_1, and a discharge transistor 636 electrically coupled between a second power node carrying the higher supply voltage VDD and bit line BL[#]_1. In this example, the gate terminals of pre-charge transistors 632 and 634 are configured to receive a pre-charge signal, and the gate terminal of discharge transistor 636 is configured to receive a discharge bar signal (labeled as “/DC”) that is a logically complementary signal of discharge signal DC.

Moreover, in FIG. 6B, sense circuitry 622 further includes two single-bit data sampling devices 642 and 644 having data input nodes (labeled as ‘D’ therein) electrically coupled to bit line BL[#]_0, and a single-bit data sampling device 646 having a data input node (labeled as ‘D’ therein) electrically coupled to bit line BL[#]_1. In FIG. 6B, single-bit data sampling devices 646, 644, and 642 have output nodes (labeled as ‘Q’ therein) configured to provide output signals S[0][0], S[0][1], and S[1][0] constituting a three-bit output data of sense circuitry 622. In some embodiments, each one of the single-bit data sampling devices 642, 644, and 646 corresponds to a flip-flop or a latch. In this example, sampling clock signal CK[0] is applied to clock or enable nodes (labeled as ‘CLK’ therein) of single-bit data sampling devices 644 and 646, and sampling clock signal CK[1] is applied to a clock or enable node of single-bit data sampling device 642. In this example, decoder 624 is configured to convert the output signals S[0][0], S[0][1], and S[1][0] from sense circuitry 622 into binary data O[#]_0 and O[#]_1 as output.

In some embodiments, as similarly described with respect to the examples in FIGS. 4A-4E, except for the inversion of the polarities of output signals S[0][0], S[0][1], and S[1][0], the portion of output circuitry 620 is configured to detect the electrical coupling relationship between the two drain/source terminals of an activated memory cell (activated by a corresponding word line) and the set of three (3) bit lines based on two (2) reading stages.

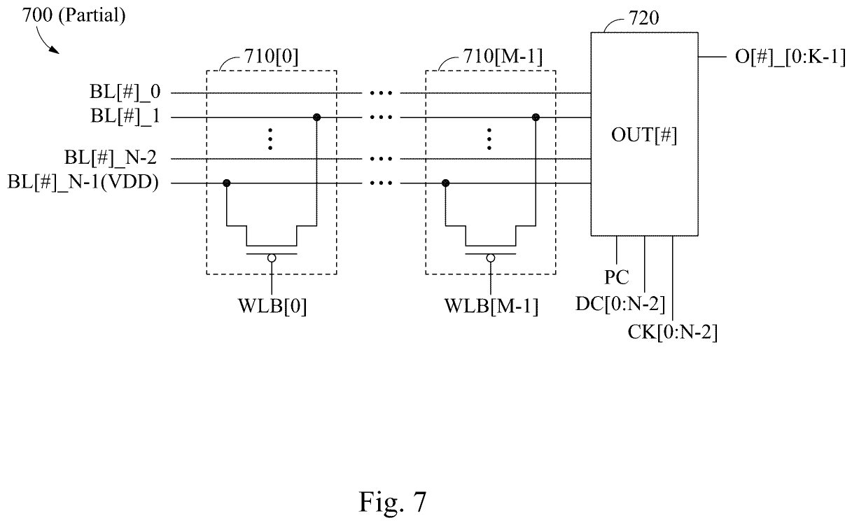

FIG. 7 is a schematic diagram of a portion of memory device 700 (labeled as “700 (Partial)), including a column of memory cells 710[0]-710[M−1] in association with a set of bit lines BL[#]_0-BL[#]_N−1, and including a portion of an output circuitry 720 of memory device 700 electrically coupled to the set of bit lines, in accordance with some embodiments. In this example, ‘#’ in FIG. 7 corresponds to a number from 0 to (L−1).

In some embodiments, similar to the example in FIG. 5A being based on a generalization of the example in FIG. 3B, the portion of memory device 700 in FIG. 7 is based on a generalization of the example in FIG. 6A, with N being an integer equal to or greater than three (3). For example, the column of memory cells 710[0]-710[M−1] is configured based on the example of FIGS. 2C and 2D (with the modifications based on replacing the n-type transistors with p-type transistors) in conjunction with a set of N bit lines of such column. As such, memory device 700 also corresponds to a variation of memory device 500 based on including p-type transistors in the memory cells together with suitable adjustments to the polarities of various control signals of memory device 500.

In this non-limiting example, bit line BL[#]_N−1 is configured to carry a higher supply voltage, and bit line BL[#]_N−1 is labeled as “BL[#]_N−1 (VDD)” in FIG. 7. Moreover, in FIG. 7, the portion of output circuitry 720 is configured to receive a pre-charge signal (labeled as “PC”), a set of discharge signals (labeled as “DC[0:N−2]”), and a set of sampling clock signals (labeled as CK[0:N−2]). In FIG. 7, the portion of output circuitry 720 is configured to output a decoded binary data (labeled as O[#]_[0:K−1], where K=┘log₂ I┌, and

$$I = \{ \frac{1}{2} N ( N - 1 ) + 1 \} ) .$$

In some embodiments, as similarly described with respect to the examples in FIGS. 4A-4E, except for the inversion of the polarities of output signals, the portion of output circuitry 720 is configured to detect the electrical coupling relationship between the two drain/source terminals of an activated memory cell (activated by a corresponding word line) and the set of N bit lines based on (N−1) reading stages.

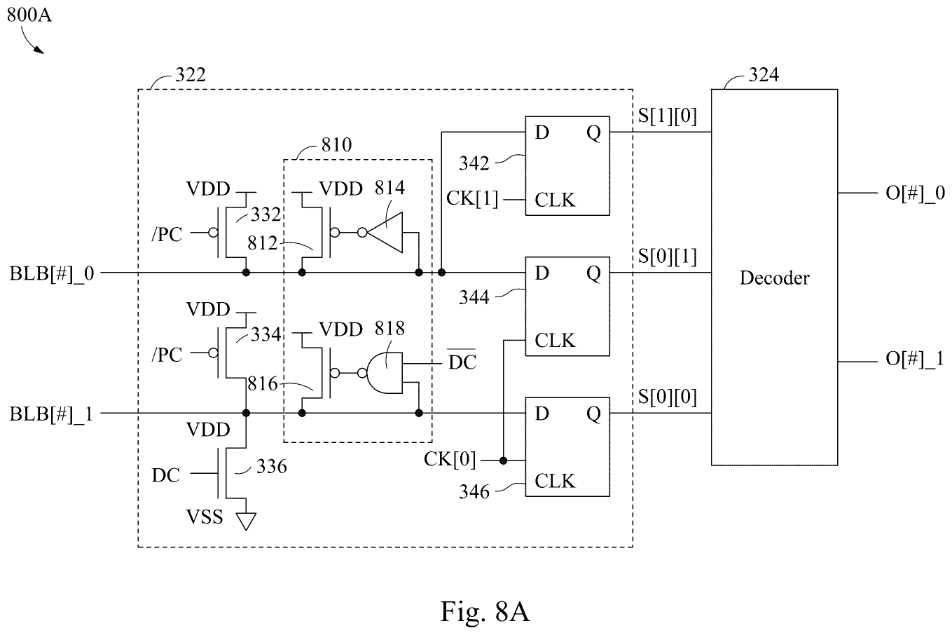

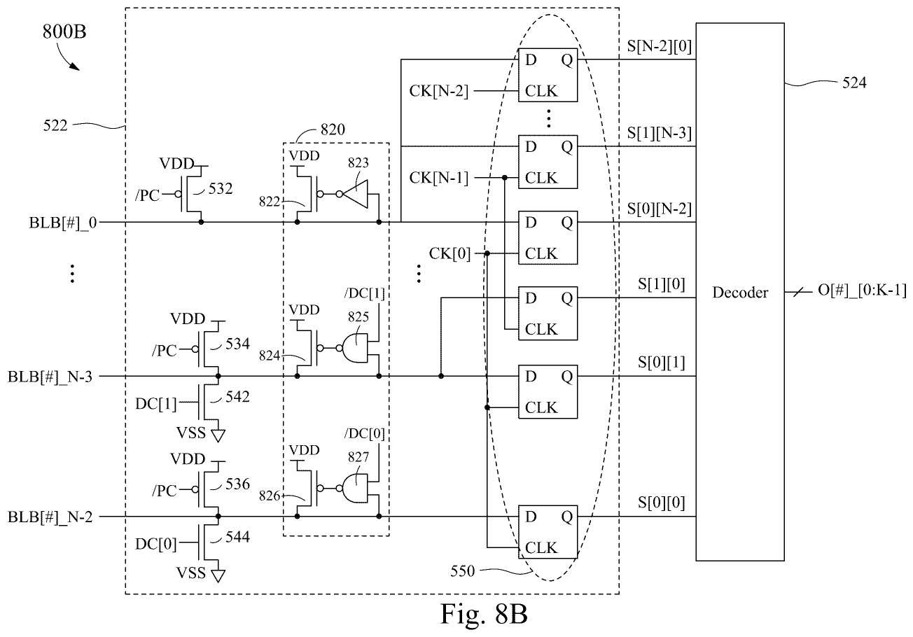

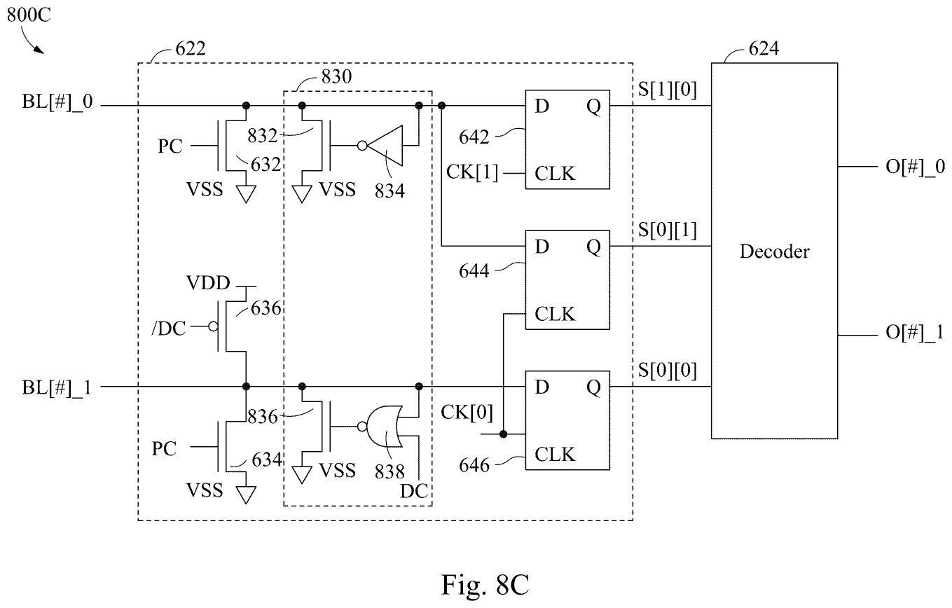

FIG. 8A is a schematic diagram of a portion of an output circuitry example 800A that includes holders 810, in accordance with some embodiments. In some embodiments, output circuitry example 800A is based on adding holders 810 to output circuitry example 320 in FIG. 3C. As such, components in FIG. 8A that are the same or similar to those in FIG. 3C are given the same reference numbers and reference labels, and description thereof is simplified or omitted.

In FIG. 8A, holders 810 of output circuitry example 800A includes 2 holders electrically coupled between a power node (e.g., carrying the higher supply voltage VDD) and bit lines including bit line BLB[#]_0 and bit line BLB[#]_1. In this example, a first holder includes a p-type transistor 812 and an inverter 814. P-type transistor 812 includes a drain/source terminal electrically coupled to the power node and another drain/source terminal electrically coupled to bit line BLB[#]_0. Inverter 814 includes an input terminal electrically coupled to bit line BLB[#]_0 and an output terminal electrically coupled to a gate terminal of p-type transistor 812. In some embodiments, the first holder is configured to pull the voltage level at bit line BLB[#]_0 toward the higher supply voltage VDD.

In FIG. 8A, a second holder includes a p-type transistor 816 and a NAND gate 818. P-type transistor 816 includes a drain/source terminal electrically coupled to the power node and another drain/source terminal electrically coupled to bit line BLB[#]_1. NAND gate 818 includes a first input terminal electrically coupled to bit line BLB[#]_1 and an output terminal electrically coupled to a gate terminal of p-type transistor 816. NAND gate 818 further includes a second input terminal configured to receive a discharge bar signal (denoted as “/DC”) that is a logically complementary signal of discharge signal DC. In some embodiments, the second holder is turned off based on the discharge bar signal/DC is at VSS and turned on based on the discharge bar signal/DC is at VDD. In some embodiments, based on the second holder being turned on (discharge bar signal/DC at VDD, which corresponds to discharge signal DC at VSS and the discharge transistor 336 being turned off), the second holder is configured to pull the voltage level at bit line BLB[#]_1 toward the higher supply voltage VDD.

FIG. 8B is a schematic diagram of a portion of an output circuitry example 800B that includes holders 820, in accordance with some embodiments. In some embodiments, output circuitry example 800B is based on adding holders 820 to output circuitry example 520 in FIG. 5B. As such, components in FIG. 8B that are the same or similar to those in FIG. 5B are given the same reference numbers and reference labels, and description thereof is simplified or omitted.

In FIG. 8B, holders 820 of output circuitry example 800B includes (N−1) holders electrically coupled between a power node (e.g., carrying the higher supply voltage VDD) and a first bit line (e.g., bit line BLB[#]_0) through an (N−1)-th bit line (e.g., bit line BLB[#]_N−2) of the corresponding set of N bit lines. For example, a first holder includes a p-type transistor 822 and an inverter 823 electrically coupled between the power node and bit line BLB[#]_0 based on a configuration similar to that of the first holder in FIG. 8A. In FIG. 8B, an (N−2)-th holder includes a p-type transistor 824 and a NAND gate 825 electrically coupled between the power node and bit line BLB[#]_N−3 based on a configuration similar to that of the second holder in FIG. 8A and configured to be turned on or off based on a discharge bar signal/DC[1]. Also, in FIG. 8B, an (N−1)-th holder includes a p-type transistor 826 and a NAND gate 827 electrically coupled between the power node and bit line BLB[#]_N−2 based on a configuration similar to that of the second holder in FIG. 8A and configured to be turned on or off based on a discharge bar signal/DC[0].

FIG. 8C is a schematic diagram of a portion of an output circuitry example 800C that includes holders 830, in accordance with some embodiments. In some embodiments, output circuitry example 800C is based on adding holders 830 to output circuitry example 620 in FIG. 6B. As such, components in FIG. 8C that are the same or similar to those in FIG. 6B are given the same reference numbers and reference labels, and description thereof is simplified or omitted.

In FIG. 8C, holders 830 of output circuitry example 800C includes 2 holders electrically coupled between a power node (e.g., carrying the lower supply voltage VSS) and bit lines including bit line BL[#]_0 and bit line BL[#]_1. In this example, a first holder includes an n-type transistor 832 and an inverter 834. N-type transistor 832 includes a drain/source terminal electrically coupled to the power node and another drain/source terminal electrically coupled to bit line BL[#]_0. Inverter 834 includes an input terminal electrically coupled to bit line BL[#]_0 and an output terminal electrically coupled to a gate terminal of n-type transistor 832. In some embodiments, the first holder is configured to pull the voltage level at bit line BL[#]_0 toward the lower supply voltage VSS.

In FIG. 8C, a second holder includes an n-type transistor 836 and a NOR gate 838. N-type transistor 836 includes a drain/source terminal electrically coupled to the power node and another drain/source terminal electrically coupled to bit line BL[#]_1. NOR gate 838 includes a first input terminal electrically coupled to bit line BL[#]_1 and an output terminal electrically coupled to a gate terminal of n-type transistor 836. NOR gate 838 further includes a second input terminal configured to receive a discharge signal DC. In some embodiments, the second holder is turned on based on the discharge signal DC is at VSS and turned off based on the discharge bar signal DC is at VDD. In some embodiments, based on the second holder being turned on (discharge signal DC at VSS, which corresponds to discharge bar signal/DC at VDD and the discharge transistor 636 being turned off), the second holder is configured to pull the voltage level at bit line BL[#]_1 toward the lower supply voltage VSS.

Compared to output circuitry 800A in FIG. 8A, output circuitry 800C corresponds to a variation of output circuitry 800A, with modifications such as swapping the types of transistors (e.g., n-type transistors to p-type transistors and vice versa) of the pre-charge transistors, discharge transistors, swapping the polarities of various signals and supply voltages, and implementing suitable holders. In some embodiments, the output circuitry 800C corresponds to a generalization of output circuitry 800C, or a variation of output circuitry 800B in FIG. 8B, with modifications such as swapping the types of transistors (e.g., n-type transistors to p-type transistors and vice versa) of the pre-charge transistors, discharge transistors, swapping the polarities of signals and supply voltages, and implementing suitable holders.

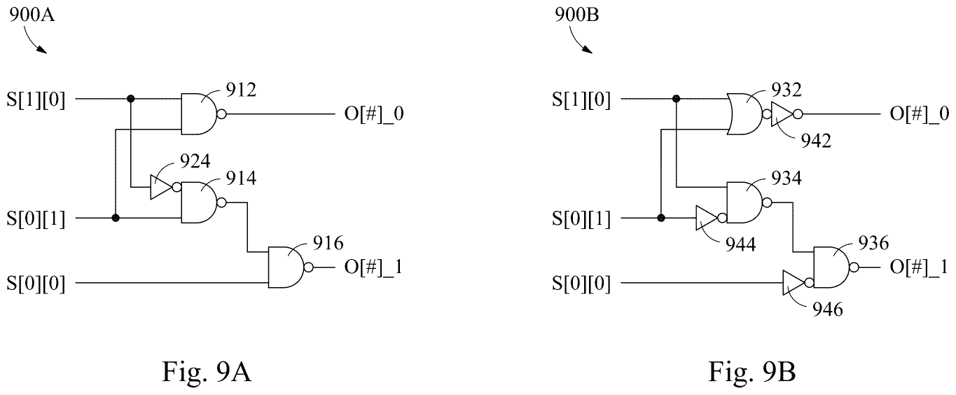

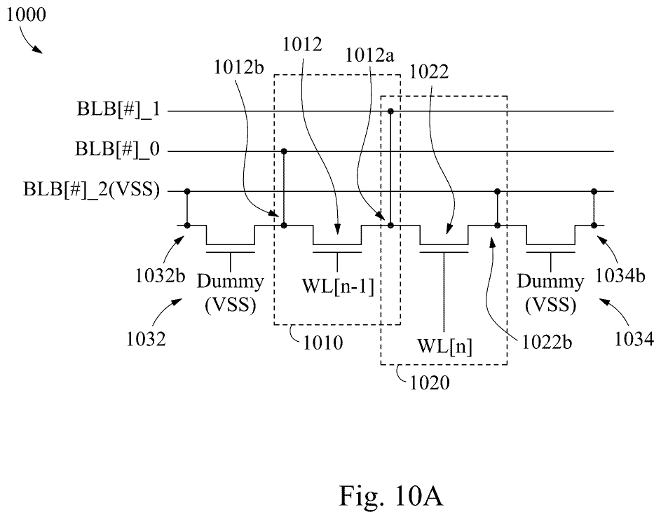

FIG. 9A is a schematic diagram of a first decoder example 900A, in accordance with some embodiments. In some embodiments, first decoder 900A is part of output circuitry 320 and corresponds to a non-limiting example of decoder 324 in FIG. 3C. Components in FIG. 9A that are the same or similar to those in FIG. 3C are given the same reference number or reference labels, and description thereof is thus simplified or omitted.

In FIG. 9A, decoder 900A includes NAND gates 912, 914, and 916 and an inverter 924. NAND gate 912 includes a first input terminal configured to receive output signal S[1][0], a second input terminal configured to receive output signal S[0][1], and an output terminal configured to output O[#]_0. NAND gate 914 includes a first input terminal configured to receive a logical complement of output signal S[1][0] (inverted by inverter 924), a second input terminal configured to receive output signal S[0][1]. NAND gate 916 includes a first input terminal electrically coupled to an output terminal of NAND gate 914, a second input terminal configured to receive output signal S[0][0], and an output terminal configured to output O[#]_1.

FIG. 9B is a schematic diagram of a second decoder example 900B, in accordance with some embodiments. In some embodiments, second decoder 900B is part of output circuitry 620 and corresponds to a non-limiting example of decoder 624 in FIG. 6B. Components in FIG. 9B that are the same or similar to those in FIG. 6B are given the same reference number or reference labels, and description thereof is thus simplified or omitted.

In FIG. 9B, decoder 900B includes a NOR gate 932 and NAND gates 934 and 936, and inverters 942, 944, and 945. NOR gate 932 includes a first input terminal configured to receive output signal S[1][0], a second input terminal configured to receive output signal S[0][1], and an output terminal configured to output a logical complement of O[#]_0. Inverter 942 is configured to receive the output from the output terminal of NOR gate 932 and output O[#]_0. NAND gate 934 includes a first input terminal configured to receive output signal S[1][0], a second input terminal configured to receive a logical complement of output signal S[0][1] (inverted by inverter 944). NAND gate 936 includes a first input terminal electrically coupled to an output terminal of NAND gate 934, a second input terminal configured to receive a logical complement of output signal S[0][0] (inverted by inverter 946), and an output terminal configured to output O[#]_1.

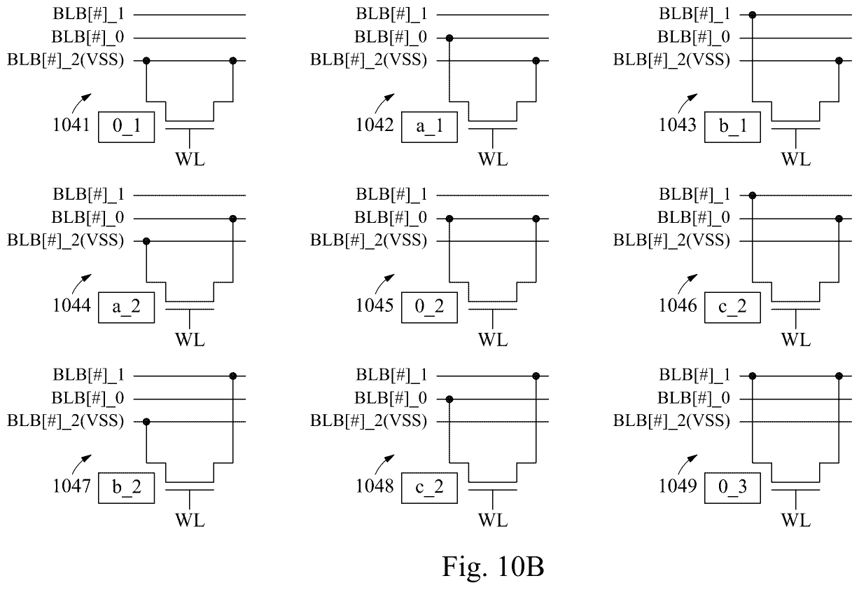

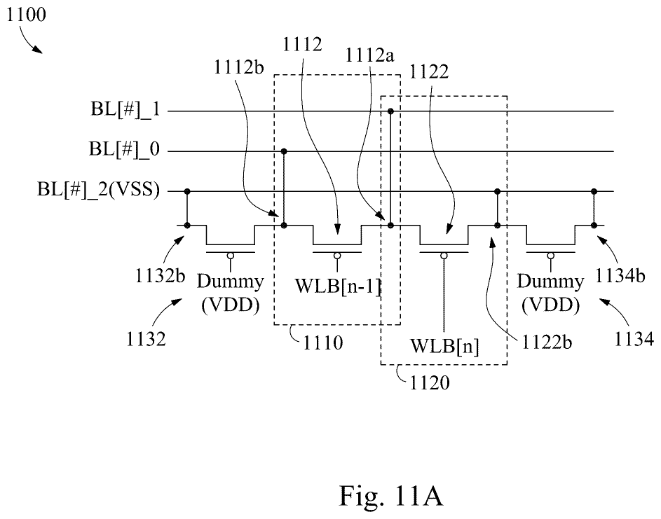

FIG. 10A is a schematic diagram of a sub-array 1000 including two memory cells 1010 and 1020 based on n-type transistors and in association with a set of bit lines BLB[#]_0, BLB[#]_1, and BLB[#]_2, in accordance with some embodiments. In this example, ‘#’ in FIGS. 10A and 10B corresponds to a number from 0 to (L−1). In this example, bit line BLB[#]_2 is configured to carry the lower supply voltage (VSS) and is denoted as “BLB[#]_2 (VSS).”

In FIG. 10A, memory cell 1010 includes an n-type transistor 1012, and memory cell 1020 includes an n-type transistor 1022. In this example, n-type transistor 1012 and n-type transistor 1022 are based on a common drain/source terminal 1012a. The gate terminal of n-type transistor 1012 is configured to receive a word line signal WL[n−1], and the gate terminal of n-type transistor 1022 is configured to receive a word line signal WL[n]. In FIG. 10A, sub-array 1000 further includes two dummy transistors 1032 and 1034. In this example, n-type transistor 1012 and dummy transistor 1032 are based on a common drain/source terminal 1012b, and n-type transistor 1022 and dummy transistor 1034 are based on a common drain/source terminal 1022b. In FIG. 10A, another drain/source terminal 1032b of dummy transistor 1032 and another drain/source terminal 1034b of dummy transistor 1034 are configured to receive the lower supply voltage VSS. The gate terminals of dummy transistors 1032 and 1034 are configured to receive the lower supply voltage VSS to turn off dummy transistors 1032 and 1034.

In this non-limiting example, while the common drain/source terminal of n-type transistor 1012 and n-type transistor 1022 imposes a constraint of arranging the electrical coupling relationship between the two drain/source terminals of n-type transistor 1012 and n-type transistor 1022 and the set of bit lines, BLB[#]_0, BLB[#]_1, and BLB[#]_2, the combination of n-type transistor 1012 and n-type transistor 1022 in FIG. 10A is still capable of representing a binary value up to

$$\{ \frac{1}{2} N ( N - 1 ) + 1 \} ( N = 3 )$$

difference information states by each one of memory cells 1010 and 1020. Accordingly, no dummy transistor is needed between n-type transistor 1012 and n-type transistor 1022 and no information state is sacrificed or omitted, which further saves the area for implementing a memory device based on sub-array 1000.

For example, FIG. 10B includes schematic diagrams 1041-1049 of a memory cell (e.g., memory cell 1010 or memory cell 1020) in FIG. 10A with various electrical coupling settings, in accordance with some embodiments. In view of the example in FIG. 2C, memory cell 1010 or memory 1020 are arranged to have nine (9) different electrical coupling relationships with respect to the set of bit lines BLB[#]_0, BLB[#]_1, and BLB[#]_2 that represent four (4) different candidate information states. In particular, in FIG. 10B, schematic diagrams 1041, 1045, and 1049 indicate three different electrical coupling settings (labeled as ‘0_1’, ‘0_2’, and ‘0_3’) that correspond to an information state of ‘0’; schematic diagrams 1042 and 1044 indicate two different electrical coupling settings (labeled as ‘a_1’ and ‘a_2’) that correspond to an information state of ‘a’; schematic diagrams 1043 and 1047 indicate two different electrical coupling settings (labeled as ‘b_1’ and ‘b_2’) that correspond to an information state of ‘b’; and schematic diagrams 1046 and 1048 indicate two different electrical coupling settings (labeled as ‘c_1’ and ‘c_2’) that correspond to an information state of ‘c’.

Accordingly, in this non-limiting example, a possible electrical coupling arrangement is listed in Table I below. In this table, column “Data (MC 1010)” corresponds to the binary data value stored by memory cell 1010, column “Data (MC 1020)” corresponds to the binary data value stored by memory cell 1020, and columns “Electrical Coupling (MC 1010)” and “Electrical Coupling (MC 1020)” correspond to possible combination of electrical coupling settings as described with respect to FIG. 10B in association with the corresponding binary data values stored by memory cells 1010 and 1020.

TABLE I

| Data | Data | Electrical Coupling | Electrical Coupling |
|---|---|---|---|
| (MC 1010) | (MC 1020) | (MC 1010) | (MC 1020) |
| 00 | 00 | 0_1 | 0_1 |
| | | 0_2 | 0_2 |
| | | 0_3 | 0_3 |
| 00 | 01 | 0_2 | a_1 |
| | | 0_1 | a_2 |
| 00 | 10 | 0_3 | b_1 |
| | | 0_1 | b_2 |
| 00 | 11 | 0_3 | c_1 |
| | | 0_2 | c_2 |
| 01 | 00 | a_1 | 0_1 |
| | | a_2 | 0_2 |
| 01 | 01 | a_2 | a_1 |
| | | a_1 | a_2 |
| 01 | 10 | a_1 | b_2 |
| 01 | 11 | a_2 | c_2 |
| 10 | 00 | b_1 | 0_1 |
| | | b_2 | 0_3 |
| 10 | 01 | b_1 | a_2 |
| 10 | 10 | b_2 | b_1 |
| | | b_1 | b_2 |
| 10 | 11 | b_2 | c_1 |
| 11 | 00 | c_1 | 0_2 |
| | | c_2 | 0_3 |
| 11 | 01 | c_1 | a_1 |
| 11 | 10 | c_2 | b_1 |
| 11 | 11 | c_2 | c_1 |
| | | c_1 | c_2 |

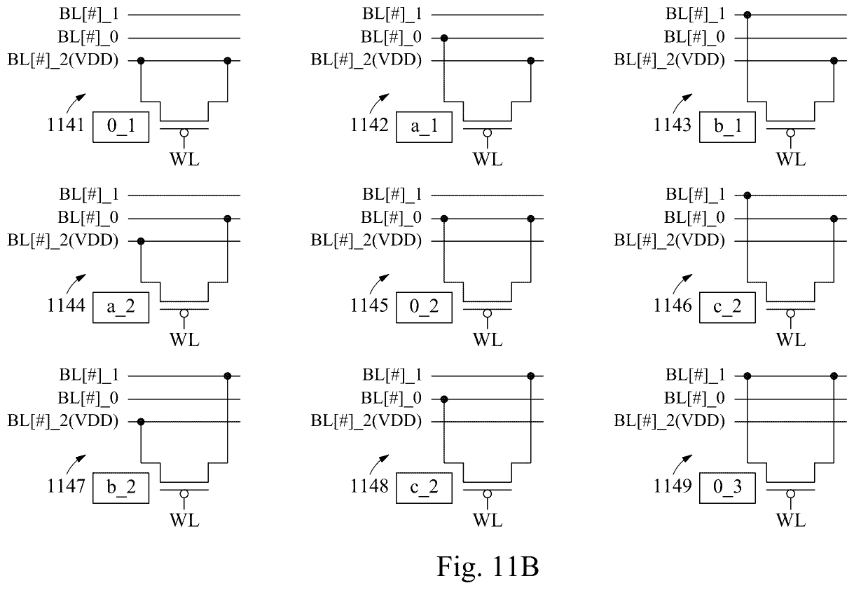

FIG. 11A is a schematic diagram of a sub-array 1100 including two memory cells 1110 and 1120 based on p-type transistors and in association with a set of bit lines BL[#]_0, BL[#]_1, and BL[#]_2, in accordance with some embodiments. In this example, ‘#’ in FIGS. 11A and 11B corresponds to a number from 0 to (L−1). In this example, bit line BL[#]_2 is configured to carry the higher supply voltage (VDD) and is denoted as “BL[#]_2 (VDD).” In some embodiments, sub-array 1100 corresponds to a variation based on sub-array 1000, with modifications such as swapping the types of transistors (e.g., n-type transistors to p-type transistors and vice versa) and swapping the polarities of signals and supply voltages.

In FIG. 11A, memory cell 1110 includes a p-type transistor 1112, and memory cell 1120 includes a p-type transistor 1122. In this example, p-type transistor 1112 and p-type transistor 1122 are based on a common drain/source terminal 1112a. The gate terminal of p-type transistor 1112 is configured to receive a word line signal WLB[n−1], and the gate terminal of p-type transistor 1122 is configured to receive a word line signal WLV[n]. In FIG. 11A, sub-array 1100 further includes two dummy transistors 1132 and 1134. In this example, p-type transistor 1112 and dummy transistor 1132 are based on a common drain/source terminal 1112b, and p-type transistor 1122 and dummy transistor 1134 are based on a common drain/source terminal 1122b. In FIG. 11A, another drain/source terminal 1132b of dummy transistor 1132 and another drain/source terminal 1134b of dummy transistor 1134 are configured to receive the higher supply voltage VDD. The gate terminals of dummy transistors 1132 and 1134 are configured to receive the higher supply voltage VDD to turn off dummy transistors 1132 and 1134.

In this non-limiting example, similar to the example in FIGS. 10A and 10B, while the common drain/source terminal of p-type transistor 1112 and p-type transistor 1122 imposes a constraint of arranging the electrical coupling relationship between the two drain/source terminals of p-type transistor 1112 and p-type transistor 1122 and the set of bit lines, BL[#]_0, BL[#]_1, and BL[#]_2, the combination of p-type transistor 1112 and p-type transistor 1122 in FIG. 11A is still capable of representing a binary value up to

$$\{ \frac{1}{2} N ( N - 1 ) + 1 \} ( N = 3 )$$

difference information states by each one of memory cells 1110 and 1120. Accordingly, no dummy transistor is needed between p-type transistor 1112 and p-type transistor 1122 and no information states is sacrificed or omitted, which further saves the areas for implementing a memory device based on sub-array 1100.

For example, FIG. 11B includes schematic diagrams 1141-1149 of a memory cell (e.g., memory cell 1110 or memory cell 1120) in FIG. 11A with various electrical coupling settings, in accordance with some embodiments. In view of the example in FIG. 2C, memory cell 1110 or memory 1120 are arranged to have nine (9) different electrical coupling relationships with respect to the set of bit lines BL[#]_0, BL[#]_1, and BL[#]_2 that represent four (4) different candidate information states. In particular, in FIG. 11B, schematic diagrams 1141, 1145, and 1149 indicate three different electrical coupling settings (labeled as ‘0_1’, ‘0_2’, and ‘0_3’) that correspond to an information state of ‘0’; schematic diagrams 1142 and 1144 indicate two different electrical coupling settings (labeled as ‘a_1’ and ‘a_2’) that correspond to an information state of ‘a’; schematic diagrams 1143 and 1147 indicate two different electrical coupling settings (labeled as ‘b_1’ and ‘b_2’) that correspond to an information state of ‘b’; and schematic diagrams 1146 and 1148 indicate two different electrical coupling settings (labeled as ‘c_1’ and ‘c_2’) that correspond to an information state of ‘c’.

Accordingly, in this non-limiting example, a possible electrical coupling arrangement is listed in Table II below. In this table, column “Data (MC 1110)” corresponds to the binary data value stored by memory cell 1110, column “Data (MC 1120)” corresponds to the binary data value stored by memory cell 1120, and columns “Electrical Coupling (MC 1110)” and “Electrical Coupling (MC 1120)” correspond to possible combination of electrical coupling settings as described with respect to FIG. 11B in association with the corresponding binary data values stored by memory cells 1110 and 1120.

TABLE II

| Data | Data | Electrical Coupling | Electrical Coupling |
|---|---|---|---|
| (MC 1110) | (MC 1120) | (MC 1110) | (MC 1120) |
| 00 | 00 | 0_1 | 0_1 |
| | | 0_2 | 0_2 |
| | | 0_3 | 0_3 |
| 00 | 01 | 0_2 | a_1 |
| | | 0_1 | a_2 |
| 00 | 10 | 0_3 | b_1 |
| | | 0_1 | b_2 |
| 00 | 11 | 0_3 | c_1 |
| | | 0_2 | c_2 |
| 01 | 00 | a_1 | 0_1 |
| | | a_2 | 0_2 |
| 01 | 01 | a_2 | a_1 |
| | | a_1 | a_2 |
| 01 | 10 | a_1 | b_2 |
| 01 | 11 | a_2 | c_2 |
| 10 | 00 | b_1 | 0_1 |
| | | b_2 | 0_3 |
| 10 | 01 | b_1 | a_2 |
| 10 | 10 | b_2 | b_1 |
| | | b_1 | b_2 |
| 10 | 11 | b_2 | c_1 |
| 11 | 00 | c_1 | 0_2 |
| | | c_2 | 0_3 |
| 11 | 01 | c_1 | a_1 |
| 11 | 10 | c_2 | b_1 |
| 11 | 11 | c_2 | c_1 |
| | | c_1 | c_2 |

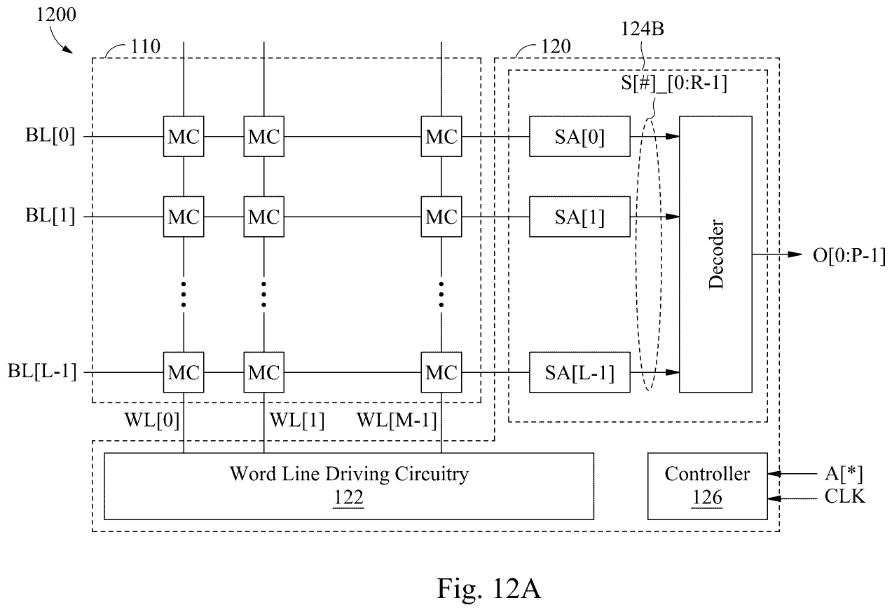

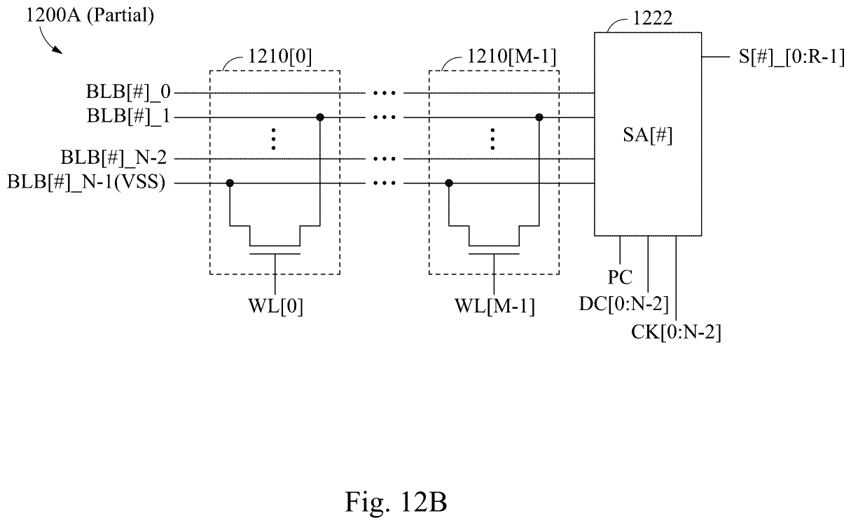

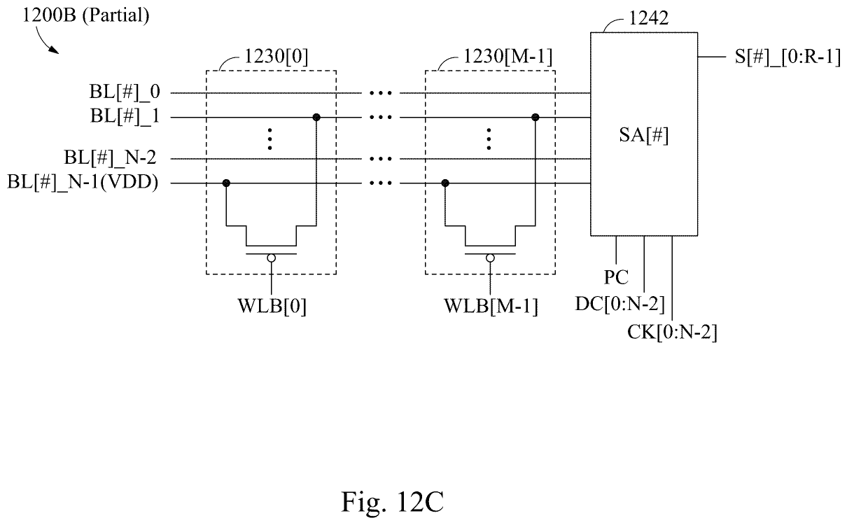

FIG. 12A is a schematic block diagram of a memory device 1200 based on a second output circuitry configuration, in accordance with some embodiments. In some embodiments, memory device 1200 corresponds to a variation of memory device 300 in FIG. 3A and also corresponds to an implementation based on memory device 100 in FIG. 1 and the memory cell example in FIG. 2A. As such, components in FIG. 12A that are the same or similar to those in FIG. 3A and FIG. 1 are given the same reference number or reference labels, and description thereof is simplified or omitted.

Compared to memory device 300, memory device 1200 includes output circuitry 124B in place of output circuitry 124A. In this non-limiting example, output circuitry 124B includes L sense circuitries (denoted as SA[0]-SA[L−1] in FIG. 12A) that are configured to detect the voltage levels at the sets of bit lines BL[0]-BL[L−1] and output sensed output signals S[#]_[0:R−1]. Here, ‘#’ in FIG. 12A corresponds to a number from 0 to (L−1), and S[#]_[0:R−1] represents the sensed output signals based on sensing the set of bit lines BL[#]. Moreover, output circuitry 124B includes a decoder (labeled as “Decoder” in FIG. 12A) that is configured to receive the sensed output signals S[#]_[0:R−1] and output a decoded binary data O[0:P−1]. In some embodiments, each set of the sets of bit lines includes N bit lines, and

$$R = \frac{1}{2} N ( N - 1 ) .$$

In some embodiments, P=┘log₂(L×I)┌, where

$$I = \{ \frac{1}{2} N ( N - 1 ) + 1 \} .$$

FIG. 12B is a schematic diagram of a portion of memory device 1200A (labeled as “1200A (Partial)), including a column of memory cells 1210[0]-1210[M−1] in association with a set of bit lines BLB[#]_0-BLB[#]_N−1, and including a sense circuitry 1222 (denoted as “SA[#]”), in accordance with some embodiments. In some embodiments, memory device 1200A is implemented based on memory device 1200 in FIG. 12A, where each one of memory cells 1210[0]-1210[M−1] is based on a corresponding n-type transistor as similarly described with respect to the example in FIGS. 5A-5B. In FIG. 12B, ‘#’ corresponds to a number from 0 to (L−1).

Compared to the portion of memory device 500 in FIGS. 5A and 5B, the decoder in FIG. 12B is shared by a plurality of columns of memory cells and the corresponding sense circuitries. Each sense circuitry (e.g., sense circuitry SA[#]) for a corresponding column of memory cells in association with a set of N bit lines is configured to provide output signals S[#]_[0:R−1], where

$$R = \frac{1}{2} N ( N - 1 ) .$$

FIG. 12C is a schematic diagram of a portion of memory device 1200B (labeled as “1200B (Partial)), including a column of memory cells 1230[0]-1230[M−1] in association with a set of bit lines BL[#]_0-BL[#]_N−1, and including a sense circuitry 1242 (labeled as “SA[#]”), in accordance with some embodiments. In some embodiments, memory device 1200B is implemented based on memory device 1200 in FIG. 12A, where each one of memory cells 1230[0]-1230[M−1] is based on a corresponding p-type transistor as similarly described with respect to the example in FIG. 7. In FIG. 12C, ‘#’ corresponds to a number from 0 to (L−1).

Compared to the portion of memory device 700 in FIG. 7, the decoder in FIG. 12C is shared by a plurality of columns of memory cells and the corresponding sense circuitries. Each sense circuitry (e.g., sense circuitry SA[#]) for a corresponding column of memory cells in association with a set of N bit lines is configured to provide output signals S[#]_[0:K−1], where

$$R = \frac{1}{2} N ( N - 1 ) .$$

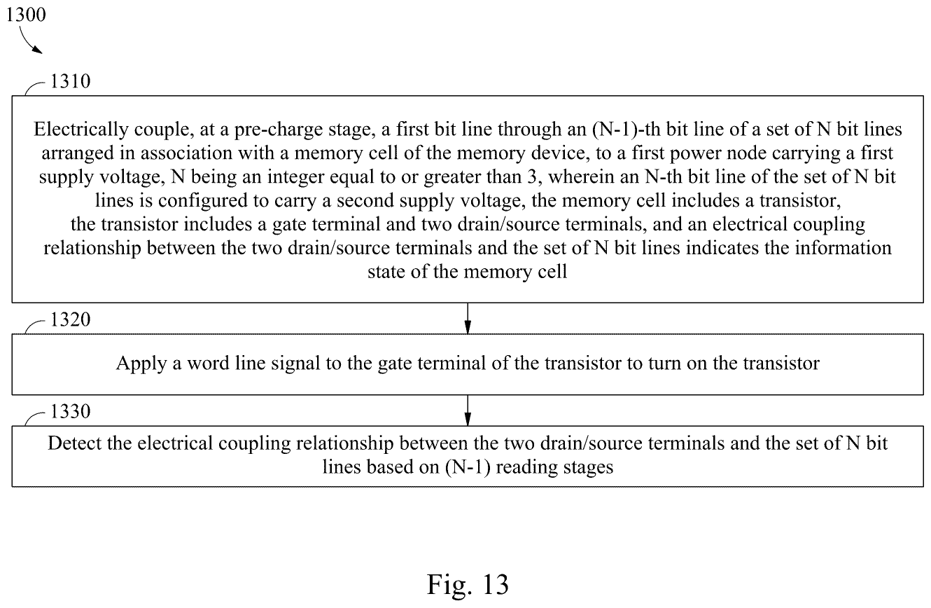

FIG. 13 is a flowchart of a method 1300 of detecting an information state of a memory cell of a memory device, in accordance with some embodiments. In some embodiments, the memory device in method 1300 corresponds to memory device 300 in FIG. 3B, memory device 500 in FIG. 5A, memory device 600 in FIG. 6A, or memory device 700 in FIG. 7, in view of various configurations and/or variations in the examples of FIGS. 8A-12C. Method 1300 includes blocks 1310-1330.

At block 1310, at a pre-charge stage, a first bit line through an (N−1)-th bit line of a set of N bit lines arranged in association with a memory cell of the memory device are electrically coupled to a first power node carrying a first supply voltage, as illustrated in the example of FIG. 4A or in the example of FIG. 5C prior to time T1 based on a pre-charge signal PC. In some embodiments, N is an integer equal to or greater than 3. In some embodiments, as described in various examples above, an N-th bit line of the set of N bit lines is configured to carry a second supply voltage (e.g., BLB[#]_N−1 to VSS or BL[#]_N−1 to VDD). In some embodiments, as described in the example in FIGS. 2A-2D, the memory cell includes a transistor, the transistor includes a gate terminal and two drain/source terminals, and an electrical coupling relationship between the two drain/source terminals and the set of N bit lines indicates the information state of the memory cell.

At block 1320, a word line signal is electrically coupled to the gate terminal of the transistor to turn on the transistor, as illustrated in the example of FIG. 4A or in the example of FIG. 5C at time T2 based on a word line signal WL.

At block 1330, the electrical coupling relationship between the two drain/source terminals and the set of N bit lines is determined based on (N−1) reading stages. In some embodiments, block 1330 includes determining, during a first reading stage of the (N−1) reading stages, one of the two drain/source terminals being electrically coupled to the N-th bit line and the other one of the two drain/source terminals being electrically coupled to one of the first bit line through an (N−1)-th bit line based on a discharging status of the first bit line through the (N−1)-th bit line, as illustrated in the example of FIG. 4A or in the example of FIG. 5C between time T2 and T3.

In some embodiments, block 1330 further includes, for each index i ranging from 2 to (N−1), executing an i-th reading stage of the (N−1) reading stages, as illustrated in the example of FIG. 4A between time T3 and T4 or in the example of FIG. 5C between time TN and TN+1. In some embodiments, the i-th reading stage includes electrically coupling, during the i-th reading stage, an (N−i+1)-th bit line to a second power node carrying the second supply voltage. In some embodiments, the i-th reading stage further includes determining, during the i-th reading stage, one of the two drain/source terminals being electrically coupled to the (N−i+1)-th bit line and the other one of the two drain/source terminals is electrically coupled to one of the first bit line through an (N−i)-th bit line based on a discharging status of the first bit line through the (N−i)-th bit line, or the two drain/source terminals being electrically coupled to a same bit line of the set of N bit lines based on the discharging status of the first bit line through the (N−i)-th bit line and based on i being (N−1). In some embodiments, method 1300 further includes converting the information state of the memory cell indicated by the detected electrical coupling relationship into a binary data.

In some embodiments, the detecting the electrical coupling relationship between the two drain/source terminals and the set of N bit lines based on the (N−1) reading stages is performed by a sense circuitry (e.g., sense circuitry 322 in FIG. 3C, sense circuitry 522 in FIG. 5B, sense circuitry 622 in FIG. 6B, or the examples in FIGS. 8A-8C). In some embodiments, the sense circuitry includes (N−1) pre-charge transistors electrically coupled between the first power node carrying the first supply voltage and corresponding ones of a corresponding set of N bit lines, and (N−2) discharge transistors electrically coupled between the second power node carrying the second supply voltage and second one through (N−1)-th one of the corresponding set of N bit lines, an N-th bit line of the corresponding set of N bit lines being configured to carry the second supply voltage. In some embodiments, the sense circuitry further includes

$$\frac{1}{2} N ( N - 1 )$$

single-bit data sampling device(s), including, for each index i ranging from 1 to (N−1), (N−i) single-bit data sampling device(s) having data input node(s) electrically coupled to i-th one of the corresponding set of N bit lines. In some embodiments, the detecting the electrical coupling relationship between the two drain/source terminals and the set of N bit lines based on the (N−1) reading stages further includes, for each index i ranging from 1 to (N−1), enabling, during the i-th reading stage of the (N−1) reading stages, the (N−i) single-bit data sampling device(s) having data input node(s) electrically coupled to a first bit line through an (N−i)-th bit line of the corresponding set of N bit lines to obtain (N−i) sampled data; and obtaining

$$\frac{1}{2} N ( N - 1 )$$

bits of data from corresponding output nodes of the

$$\frac{1}{2} N ( N - 1 )$$

single-bit data sampling devices, the information state of the memory cell being indicated based on the

$$\frac{1}{2} N ( N - 1 )$$

bits of data.

In some embodiments, the electrically coupling, at the pre-charge stage, the first bit line through the (N−1)-th bit line of the set of N bit lines to the first power node includes applying a pre-charge signal to the (N−1) pre-charge transistors. In some embodiments, for each index i ranging from 2 to (N−1), the electrically coupling, during the i-th reading stage, the (N−i+1)-th bit line to the second power node includes applying an (i−1)-th discharging signal to an (N−i+1)-th discharge transistors of the (N−2) discharge transistors. In some embodiments, the sense circuitry further comprises (N−1) holders electrically coupled between the first power node and a first bit line through an (N−1)-th bit line of the set of N bit lines. In some embodiments, the detecting the electrical coupling relationship between the two drain/source terminals and the set of N bit lines based on the (N−1) reading stages further includes, for each index i ranging from 2 to (N−1), applying, during the i-th reading stage, turning off an (N−i+1)-th holder coupled to the (N−i+1)-th bit line based on the (i−1)-th discharging signal or a logically complementary signal of the (i−1)-th discharging signal.

In some embodiments, each one of the

$$\frac{1}{2} N ( N - 1 )$$

single-bit data sampling device(s) corresponds to a flip-flop or a latch. In some embodiments, the detecting the electrical coupling relationship between the two drain/source terminals and the set of N bit lines based on the (N−1) reading stages further includes, for each index i ranging from 1 to (N−1), applying, during the i-th reading stage, an i-th sampling clock signal to clock or enable node(s) of (N−i) single-bit data sampling devices that are electrically coupled to a first bit line through an (N−i)-th bit line of the set of N bit lines.

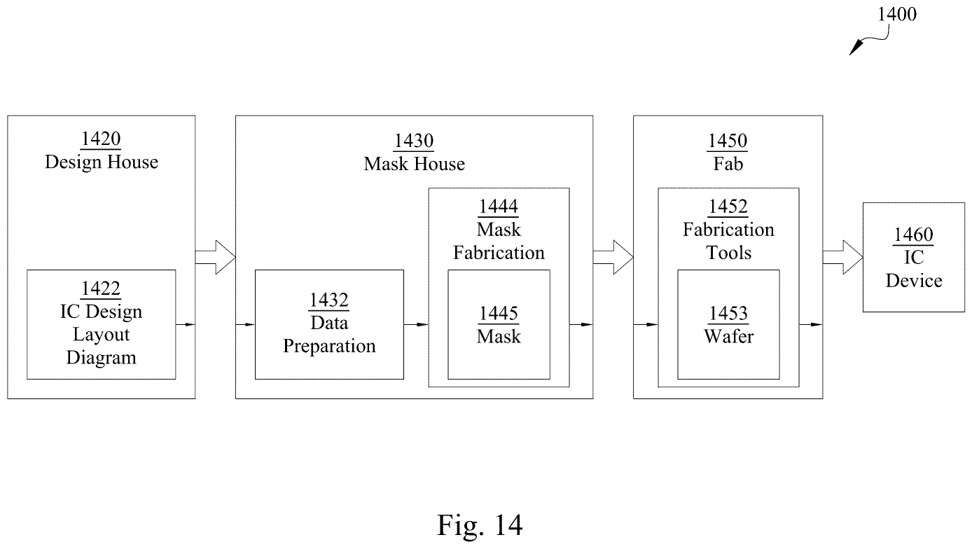

FIG. 14 is a block diagram of an IC manufacturing system 1400, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1400.

In FIG. 14, IC manufacturing system 1400 includes entities, such as a design house 1420, a mask house 1430, and an IC manufacturer/fabricator (fab) 1450, that interact with one another in the design, development, and manufacturing cycles and/or services related to manufacturing an IC device 1460. The entities in system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1420, mask house 1430, and IC fab 1450 is owned by a single larger company. In some embodiments, two or more of design house 1420, mask house 1430, and IC fab 1450 coexist in a common facility and use common resources.

Design house (or design team) 1420 generates an IC design layout diagram 1422 (e.g., a layout plan). IC design layout diagram 1422 includes various geometrical patterns designed for an IC device 1460. The geometrical patterns correspond to patterns of metal, oxide, or semiconductor layers that make up the various components of IC device 1460 to be fabricated. The various layers combine to form various IC features. For example, a portion of IC design layout diagram 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1420 implements a proper design procedure to form IC design layout diagram 1422. The design procedure includes one or more of logic design, physical design or place and route. IC design layout diagram 1422 is presented in one or more data files having information of the geometrical patterns. For example, IC design layout diagram 1422 can be expressed in a GDSII file format or DFII file format.

Mask house 1430 includes data preparation 1432 and mask fabrication 1444. Mask house 1430 uses IC design layout diagram 1422 to manufacture one or more masks 1445 to be used for fabricating the various layers of IC device 1460 according to IC design layout diagram 1422. Mask house 1430 performs mask data preparation 1432, where IC design layout diagram 1422 is translated into a representative data file (RDF). Mask data preparation 1432 provides the RDF to mask fabrication 1444. Mask fabrication 1444 includes a mask writer. A mask writer converts the RDF to an image on a substrate, such as a mask (reticle) 1445 or a semiconductor wafer 1453. The design layout diagram 1422 is manipulated by mask data preparation 1432 to comply with particular characteristics of the mask writer and/or requirements of IC fab 1450. In FIG. 14, mask data preparation 1432 and mask fabrication 1444 are illustrated as separate elements. In some embodiments, mask data preparation 1432 and mask fabrication 1444 can be collectively referred to as mask data preparation.

In some embodiments, mask data preparation 1432 includes optical proximity correction (OPC) which uses lithography enhancement techniques to compensate for image errors, such as those that can arise from diffraction, interference, other process effects and the like. OPC adjusts IC design layout diagram 1422. In some embodiments, mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1432 includes a mask rule checker (MRC) that checks the IC design layout diagram 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1422 to compensate for photolithographic implementation effects during mask fabrication 1444, which may undo part of the modifications performed by OPC in order to meet mask creation rules.

In some embodiments, mask data preparation 1432 includes lithography process checking (LPC) that simulates processing that will be implemented by IC fab 1450 to fabricate IC device 1460. LPC simulates this processing based on IC design layout diagram 1422 to create a simulated manufactured device, such as IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1422.

It should be understood that the above description of mask data preparation 1432 has been simplified for the purposes of clarity. In some embodiments, data preparation 1432 includes additional features such as a logic operation (LOP) to modify the IC design layout diagram 1422 according to manufacturing rules. Additionally, the processes applied to IC design layout diagram 1422 during data preparation 1432 may be executed in a variety of different orders.

After mask data preparation 1432 and during mask fabrication 1444, a mask 1445 or a group of masks 1445 are fabricated based on the modified IC design layout diagram 1422. In some embodiments, mask fabrication 1444 includes performing one or more lithographic exposures based on IC design layout diagram 1422. In some embodiments, an electron-beam (e-beam) or a mechanism of multiple e-beams is used to form a pattern on a mask (photomask or reticle) 1445 based on the modified IC design layout diagram 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1450 is an IC fabrication business that includes one or more manufacturing facilities for the fabrication of a variety of different IC products. In some embodiments, IC fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1450 includes fabrication tools 1452 configured to execute various manufacturing operations on semiconductor wafer 1453 such that IC device 1460 is fabricated in accordance with the mask(s), e.g., mask 1445. In various embodiments, fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1450 uses mask(s) 1445 fabricated by mask house 1430 to fabricate IC device 1460. Thus, IC fab 1450 at least indirectly uses IC design layout diagram 1422 to fabricate IC device 1460. In some embodiments, semiconductor wafer 1453 is fabricated by IC fab 1450 using mask(s) 1445 to form IC device 1460. In some embodiments, the IC fabrication includes performing one or more lithographic exposures based at least indirectly on IC design layout diagram 1422. Semiconductor wafer 1453 includes a silicon substrate or other proper substrate having material layers formed thereon. Semiconductor wafer 1453 further includes one or more of various doped regions, dielectric features, multilevel interconnects, and the like (formed at subsequent manufacturing steps).

In some aspects, a memory device includes a memory cell array including a plurality of memory cells arranged in rows and columns, a plurality of word lines arranged in association with corresponding rows of memory cells of the memory cell array, and a plurality of sets of N bit lines arranged in association with corresponding columns of memory cells of the memory cell array, N being an integer equal to or greater than 3. Each memory cell of the memory cell array includes a transistor including a gate terminal and two drain/source terminals, the gate terminal being electrically coupled to a corresponding one of the plurality of word lines, and the two drain/source terminals being electrically coupled to a same bit line or two bit lines of a corresponding set of N bit lines of the plurality of sets of N bit lines, and an electrical coupling relationship between the two drain/source terminals and the corresponding set of N bit lines indicating one of

$$\{ \frac{1}{2} N ( N - 1 ) + 1 \}$$

candidate information states. The

$$\{ \frac{1}{2} N ( N - 1 ) + 1 \}$$

candidate information states includes

$$\frac{1}{2} N ( N - 1 )$$

candidate information states corresponding to the two drain/source terminals electrically coupled to

$$\frac{1}{2} N ( N - 1 )$$

different pairs of bit lines of the corresponding set of N bit lines and including one candidate information state corresponding to N different occasions of the two drain/source terminals electrically coupled to the same bit line of the corresponding set of N bit lines.

In some aspects, a method of detecting an information state of a memory cell of a memory device includes electrically coupling, at a pre-charge stage, a first bit line through an (N−1)-th bit line of a set of N bit lines arranged in association with a memory cell of the memory device, to a first power node carrying a first supply voltage, N being an integer equal to or greater than 3, where an N-th bit line of the set of N bit lines is configured to carry a second supply voltage. The memory cell includes a transistor, the transistor includes a gate terminal and two drain/source terminals, and an electrical coupling relationship between the two drain/source terminals and the set of N bit lines indicates the information state of the memory cell. The method includes applying a word line signal to the gate terminal of the transistor to turn on the transistor, and detecting the electrical coupling relationship between the two drain/source terminals and the set of N bit lines based on (N−1) reading stages. The (N−1) reading stages includes determining, during a first reading stage of the (N−1) reading stages, one of the two drain/source terminals being electrically coupled to the N-th bit line and the other one of the two drain/source terminals being electrically coupled to one of the first bit line through an (N−1)-th bit line based on a discharging status of the first bit line through the (N−1)-th bit line. The (N−1) reading stages includes, for each index i ranging from 2 to (N−1), executing an i-th reading stage of the (N−1) reading stages, including electrically coupling, during the i-th reading stage, an (N−i+1)-th bit line to a second power node carrying the second supply voltage; and determining, during the i-th reading stage, one of the two drain/source terminals being electrically coupled to the (N−i+1)-th bit line and the other one of the two drain/source terminals is electrically coupled to one of the first bit line through an (N−i)-th bit line based on a discharging status of the first bit line through the (N−i)-th bit line, or the two drain/source terminals being electrically coupled to a same bit line of the set of N bit lines based on the discharging status of the first bit line through the (N−i)-th bit line and based on i being (N−1).

In some aspects, a semiconductor device includes N conductive lines configured as N bit lines, another conductive line configured as a word line, and a first memory cell including a first transistor that includes a first gate terminal and two first drain/source terminals, N being an integer equal to or greater than 3. The first gate terminal is electrically coupled to the word line. The two first drain/source terminals are electrically coupled to a same bit line or between two bit lines of the N bit lines, indicating a first information state of the first memory cell that is one of

$$\{ \frac{1}{2} N ( N - 1 ) + 1 \}$$

candidate information states. The

$$\{ \frac{1}{2} N ( N - 1 ) + 1 \}$$

candidate information states include

$$\frac{1}{2} N ( N - 1 )$$

candidate information states corresponding to the two drain/source terminals electrically coupled to

$$\frac{1}{2} N ( N - 1 )$$

different pairs of bit lines of the N bit lines and one candidate information state corresponding to N different occasions of the two drain/source terminals electrically coupled to the same bit line of the N bit lines.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A memory device, comprising:
a memory cell array including a plurality of memory cells arranged in rows and columns;
a plurality of word lines arranged in association with corresponding rows of memory cells of the memory cell array; and
a plurality of sets of N bit lines arranged in association with corresponding columns of memory cells of the memory cell array, N being an integer equal to or greater than 3,
wherein each memory cell of the memory cell array comprises:
a transistor including a gate terminal and two drain/source terminals,
the gate terminal being electrically coupled to a corresponding one of the plurality of word lines,
the two drain/source terminals being electrically coupled to a same bit line or two bit lines of a corresponding set of N bit lines of the plurality of sets of N bit lines, and an electrical coupling relationship between the two drain/source terminals and the corresponding set of N bit lines indicating one of
$$\{ \frac{1}{2} N ( N - 1 ) + 1 \}$$
candidate information states, and
the
$$\{ \frac{1}{2} N ( N - 1 ) + 1 \}$$
candidate information states including
$$\frac{1}{2} N ( N - 1 )$$
candidate information states corresponding to the two drain/source terminals electrically coupled to
$$\frac{1}{2} N ( N - 1 )$$
different pairs of bit lines of the corresponding set of N bit lines and including one candidate information state corresponding to N different occasions of the two drain/source terminals electrically coupled to the same bit line of the corresponding set of N bit lines.

2. The memory device of claim 1, wherein
each transistor of the plurality of memory cells corresponds to an n-type transistor, and
each set of the plurality of sets of N bit lines includes a bit line configured to carry a lower supply voltage or a ground reference voltage.

3. The memory device of claim 1, wherein
each transistor of the plurality of memory cells corresponds to a p-type transistor, and
each set of the plurality of sets of N bit lines includes a bit line configured to carry a higher supply voltage.

4. The memory device of claim 1, wherein
the plurality of memory cells includes at least a first transistor of a first memory cell and a second transistor of a second memory cell, and
the first transistor and the second transistor are based on a common drain/source structure.

5. The memory device of claim 1, further comprising:
a plurality of sense circuitries arranged in association with corresponding sets of the plurality of sets of N bit lines,
wherein each sense circuitry of the plurality of sense circuitries comprises:
(N−1) pre-charge transistors electrically coupled between a first power node carrying a first supply voltage and corresponding ones of a corresponding set of N bit lines;
(N−2) discharge transistors electrically coupled between a second power node carrying a second supply voltage and second one through (N−1)-th one of the corresponding set of N bit lines, an N-th bit line of the corresponding set of N bit lines being configured to carry the second supply voltage; and
$$\frac{1}{2} N ( N - 1 )$$
single-bit data sampling devices, including, for each index i ranging from 1 to (N−1), (N−i) single-bit data sampling device(s) having data input node(s) electrically coupled to i-th one of the corresponding set of N bit lines.

6. The memory device of claim 5, wherein
each one of the
$$\frac{1}{2} N ( N - 1 )$$
single-bit data sampling devices corresponds to a flip-flop or a latch.

7. The memory device of claim 5, wherein
a sense circuitry of the plurality of sense circuitries is configured to receive (N−1) sampling clock signals, and
for each index i ranging from 1 to (N−1), an i-th sampling clock signal of the (N−1) sampling clock signals is applied to clock or enable node(s) of (N−i) single-bit data sampling devices that are electrically coupled to a first bit line through an (N−i)-th bit line of the corresponding set of N bit lines.

8. The memory device of claim 5, wherein
each sense circuitry of the plurality of sense circuitries further comprises (N−1) holders electrically coupled between the first power node and a first bit line through an (N−1)-th bit line of the corresponding set of N bit lines.

9. The memory device of claim 5, further comprising:
a plurality of decoders, each one of the plurality of decoders being electrically coupled to a corresponding one of the plurality of sense circuitries and configured to convert output signals from the corresponding one of the plurality of sense circuitries into binary data.

10. The memory device of claim 5, further comprising:
a decoder electrically coupled to the plurality of sense circuitries and configured to convert output signals from the plurality of sense circuitries into binary data.

11. A method of detecting an information state of a memory cell of a memory device, comprising:
electrically coupling, at a pre-charge stage, a first bit line through an (N−1)-th bit line of a set of N bit lines arranged in association with a memory cell of the memory device, to a first power node carrying a first supply voltage, N being an integer equal to or greater than 3, wherein
an N-th bit line of the set of N bit lines is configured to carry a second supply voltage,
the memory cell includes a transistor,
the transistor includes a gate terminal and two drain/source terminals, and
an electrical coupling relationship between the two drain/source terminals and the set of N bit lines indicates the information state of the memory cell;
applying a word line signal to the gate terminal of the transistor to turn on the transistor; and
detecting the electrical coupling relationship between the two drain/source terminals and the set of N bit lines based on (N−1) reading stages, including:
determining, during a first reading stage of the (N−1) reading stages, one of the two drain/source terminals being electrically coupled to the N-th bit line and the other one of the two drain/source terminals being electrically coupled to one of the first bit line through an (N−1)-th bit line based on a discharging status of the first bit line through the (N−1)-th bit line; and
for each index i ranging from 2 to (N−1), executing an i-th reading stage of the (N−1) reading stages, comprising:
electrically coupling, during the i-th reading stage, an (N−i+1)-th bit line to a second power node carrying the second supply voltage; and
determining, during the i-th reading stage, one of the two drain/source terminals being electrically coupled to the (N−i+1)-th bit line and the other one of the two drain/source terminals is electrically coupled to one of the first bit line through an (N−i)-th bit line based on a discharging status of the first bit line through the (N−i)-th bit line, or the two drain/source terminals being electrically coupled to a same bit line of the set of N bit lines based on the discharging status of the first bit line through the (N−i)-th bit line and based on i being (N−1).

12. The method of claim 11, further comprising:
converting the information state of the memory cell indicated by the detected electrical coupling relationship into binary data.

13. The method of claim 11, wherein
the detecting the electrical coupling relationship between the two drain/source terminals and the set of N bit lines based on the (N−1) reading stages is performed by a sense circuitry that includes:
(N−1) pre-charge transistors electrically coupled between the first power node carrying the first supply voltage and corresponding ones of a corresponding set of N bit lines;
(N−2) discharge transistors electrically coupled between the second power node carrying the second supply voltage and second one through (N−1)-th one of the corresponding set of N bit lines, an N-th bit line of the corresponding set of N bit lines being configured to carry the second supply voltage; and
$$\frac{1}{2} N ( N - 1 )$$
single-bit data sampling devices, including, for each index i ranging from 1 to (N−1), (N−i) single-bit data sampling device(s) having data input node(s) electrically coupled to i-th one of the corresponding set of N bit lines, and
the detecting the electrical coupling relationship between the two drain/source terminals and the set of N bit lines based on the (N−1) reading stages further comprises:
for each index i ranging from 1 to (N−1), enabling, during the i-th reading stage of the (N−1) reading stages, the (N−i) single-bit data sampling device(s) having data input node(s) electrically coupled to a first bit line through an (N−i)-th bit line of the corresponding set of N bit lines to obtain (N−i) sampled data; and
obtaining
$$\frac{1}{2} N ( N - 1 )$$
bits of data from corresponding output nodes of the
$$\frac{1}{2} N ( N - 1 )$$
single-bit data sampling devices, the information state of the memory cell being indicated based on the
$$\frac{1}{2} N ( N - 1 )$$
bits of data.

14. The method of claim 13, wherein
the electrically coupling, at the pre-charge stage, the first bit line through the (N−1)-th bit line of the set of N bit lines to the first power node comprises applying a pre-charge signal to the (N−1) pre-charge transistors, and
for each index i ranging from 2 to (N−1), the electrically coupling, during the i-th reading stage, the (N−i+1)-th bit line to the second power node comprises applying an (i−1)-th discharging signal to an (N−i+1)-th discharge transistors of the (N−2) discharge transistors.

15. The method of claim 14, wherein
the sense circuitry further comprises (N−1) holders electrically coupled between the first power node and a first bit line through an (N−1)-th bit line of the set of N bit lines, and
the detecting the electrical coupling relationship between the two drain/source terminals and the set of N bit lines based on the (N−1) reading stages further comprises:
for each index i ranging from 2 to (N−1), applying, during the i-th reading stage, turning off an (N−i+1)-th holder coupled to the (N−i+1)-th bit line based on the (i−1)-th discharging signal or a logically complementary signal of the (i−1)-th discharging signal.

16. The method of claim 13, wherein
each one of the
$$\frac{1}{2} N ( N - 1 )$$
single-bit data sampling devices corresponds to a flip-flop or a latch, and
the detecting the electrical coupling relationship between the two drain/source terminals and the set of N bit lines based on the (N−1) reading stages further comprises:
for each index i ranging from 1 to (N−1), applying, during the i-th reading stage, an i-th sampling clock signal to clock or enable node(s) of (N−i) single-bit data sampling devices that are electrically coupled to a first bit line through an (N−i)-th bit line of the set of N bit lines.

17. A semiconductor device, comprising:
N conductive lines configured as N bit lines, N being an integer equal to or greater than 3;
another conductive line configured as a word line; and
a first memory cell including a first transistor that includes a first gate terminal and two first drain/source terminals,
wherein
the first gate terminal is electrically coupled to the word line,
the two first drain/source terminals are electrically coupled to a same bit line or between two bit lines of the N bit lines, indicating a first information state of the first memory cell that is one of
$$\{ \frac{1}{2} N ( N - 1 ) + 1 \}$$
candidate information states, and
the
$$\{ \frac{1}{2} N ( N - 1 ) + 1 \}$$
candidate information states include the
$$\frac{1}{2} N ( N - 1 )$$
candidate information states corresponding to the two first drain/source terminals electrically coupled to
$$\frac{1}{2} N ( N - 1 )$$
different pairs of bit lines of the N bit lines and one candidate information state corresponding to N different occasions of the two first drain/source terminals electrically coupled to the same bit line of the N bit lines.

18. The semiconductor device of claim 17, wherein
the first transistor corresponds to an n-type transistor, and
the N bit lines include a bit line configured to carry a lower supply voltage or a ground reference voltage.

19. The semiconductor device of claim 17, wherein
the first transistor corresponds to a p-type transistor, and
the N bit lines include a bit line configured to carry a higher supply voltage.

20. The semiconductor device, of claim 17, further comprising:
a second memory cell including a second transistor that includes a second gate terminal and two second drain/source terminals,
wherein
one of the two first drain/source terminals of the first transistor and one of the two second drain/source terminals of the second transistor are based on a common drain/source structure.
